(19) United States
(12) Patent Application Publication
(10) Pub. No.: US 2024/0336633 A1
(43) Pub. Date: Oct. 10, 2024

(54) ORGANIC BORON-NITROGEN COMPOUNDS, ORGANIC ELECTRONIC DEVICES AND ELECTRONIC APPARATUSES

(71) Applicant: Shenzhen China Star Optoelectronics Semiconductor Display Technology Co., Ltd., Shenzhen (CN)

(72) Inventors: Xinlong SONG, Shenzhen (CN); Jinlong LEI, Shenzhen (CN); Ruifeng HE, Shenzhen (CN); Jingyao SONG, Shenzhen (CN)

(21) Appl. No.: 18/469,048

(22) Filed: Sep. 18, 2023

(30) Foreign Application Priority Data
Mar. 23, 2023 (CN) 202310332583.7

(51) Int. Cl. C07F 5/02; C09K 11/06; H10K 50/11; H10K 85/60

(52) U.S. Cl. CPC C07F 5/02; C09K 11/06; H10K 50/11; H10K 85/658

(57) ABSTRACT

An organic boron-nitrogen compound has a structure represented by the following Formula (I). In the Formula (I), Ar₁ is represented by the following formula

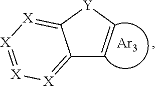

and Ar₂ is represented by any one of the following formulas:

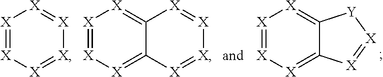

X is independently selected from CR₄ or N at each occurrence, and X is C when X is at a fused site; Y is independently selected from CR₅R₆, NR₇, S, or O at each occurrence; and Ar₃ is selected from a substituted or unsubstituted aromatic group containing 6-40 carbon atoms or a substituted or unsubstituted heteroaromatic group containing 6-40 ring atoms.

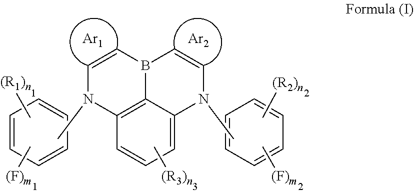

### CROSS-REFERENCE TO RELATED APPLICATION

The present disclosure claims priority to and benefit of Chinese Patent Application No. 202310332583.7, filed on Mar. 23, 2023, the present disclosure of which is incorporated herein by reference in its entirety.

### TECHNICAL FIELD

The present disclosure relates to the field of display, in particular to organic boron-nitrogen compounds, organic electronic devices, and electronic apparatuses.

### BACKGROUND

Due to organic semiconductor materials having advantageous in diversity in synthesis, relatively low manufacturing cost, and excellent optical and electrical properties, an organic electroluminescent device using the organic semiconductor materials have great potential in the application of an optoelectronic device, such as a flat panel display and an illumination device.

In order to improve luminous efficiency of the organic electroluminescent device, various light-emitting material systems based on fluorescence and phosphorescence have been developed. However, development of excellent blue light-emitting materials, whether fluorescent materials or phosphorescent materials, faces enormous challenges. In general, the current organic electroluminescent device using blue light fluorescent materials have higher reliability. However, an emission color of most blue light fluorescent materials is difficult to realize dark blue, which is not conducive to high-end display. Moreover, the synthesis of these fluorescent materials is complex, which is not conducive to large-scale production. At the same time, stability of these blue light fluorescent materials still needs to be further improved. Therefore, there is an urgent need to develop blue light fluorescent materials that have both dark blue emission spectrum and good stability. On the one hand, it is beneficial to obtain a blue light-emitting device with longer life and higher efficiency, and on the other hand, it is beneficial to realize the emission color of dark blue, thereby improving a display effect.

### SUMMARY

In a first aspect, the present disclosure provides an organic boron-nitrogen compound, which has a structure represented by the following Formula (1):

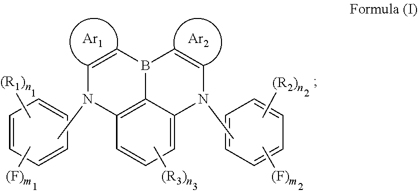

Ar₁ is represented by the following formula:

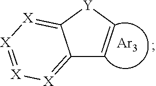

and

Ar₂ is represented by any one of the following formulas:

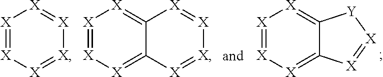

X is independently selected from CR₄ or N at each occurrence, and X is C when X is at a fused site;

Y is independently selected from CR₅R₆, NR₇, S, or O at each occurrence;

R₁-R₇ are each independently selected from H, D, a C₁₋₂₀ linear alkyl group, a C₁₋₂₀ linear alkoxyl group, a C₁₋₂₀ linear thioalkoxyl group, a C₃₋₂₀ branched alkyl group, a C₂₋₂₀ cycloalkyl group, a C₃₋₂₀ branched alkoxyl group, a C₂₋₂₀ cycloalkoxy group, a C₃₋₂₀ branched thioalkoxyl group, a C₂₋₂₀ thiocycloalkoxy group, a methylsilyl group, a ketone group, an alkoxycarbonyl group, an aryloxycarbonyl group, a substituted or unsubstituted aromatic group containing 6-40 ring atoms, a substituted or unsubstituted heteroaromatic group containing 5-40 ring atom, a substituted or unsubstituted aryloxy group containing 6-40 ring atoms, a substituted or unsubstituted heteroaryloxy group containing 5-40 ring atoms, a cyanoyl group, a carbamoyl group, a haloformyl group, a formyl group, an isocyano group, an isocyanate group, a thiocyanate group, an isothiocyanate group, a hydroxyl group, a nitro group, an amino group, CF₃, Cl, Br, F, I, or combinations thereof at each occurrence;

n₁, n₂, and n₃ are each independently selected from 0, 1, 2, or 3, m₁ and m₂ are each independently selected from 0, 1, or 2, and at least one of m₁ and m₂ is not 0; and

Ar₃ is selected from a substituted or unsubstituted aromatic group containing 6-40 carbon atoms or a substituted or unsubstituted heteroaromatic group containing 6-40 ring atoms.

In a second aspect, the present disclosure provides an organic electronic device, which includes a cathode and an anode disposed opposite to each other, and an organic functional layer disposed between the cathode and the anode. A material of the organic functional layer includes the above-mentioned organic boron-nitrogen compound.

In a third aspect, the present disclosure provides an electronic apparatus, which includes the above-mentioned organic electronic device.

### BRIEF DESCRIPTION OF THE DRAWINGS

In order to illustrate technical solutions in embodiments of the present disclosure more clearly, the following briefly introduces drawings needed to be used in description of the embodiments. Apparently, the drawings in the following description are only some embodiments of the present disclosure. For those skilled in the art, other drawings can be obtained from these drawings without paying creative effort.

FIG. 1 is a schematic cross-sectional structural diagram of an organic electronic device according to some embodiments of the present disclosure.

### DETAILED DESCRIPTION

In order to facilitate the understanding of the present disclosure, a more comprehensive description will be provided below with reference to relevant embodiments. The preferred embodiments of the present disclosure are provided in the following embodiments. However, the present disclosure can be implemented in many different forms, not limited to the embodiments described below. On the contrary, the purpose of providing these embodiments is to provide a more thorough and comprehensive understanding of the disclosed content of the present disclosure.

Unless otherwise defined, all technical and scientific terms used in this context have the same meanings as those commonly understood by those skilled in the art. The terms used in the specification of the present disclosure in this context are only for the purpose of describing specific embodiments and are not intended to limit the present disclosure. The term “and/or” used in this context includes any and all combinations of one or more related listed items.

In the present disclosure, “substituted or unsubstituted” indicates that a defined group may be substituted or not be substituted. When the defined group is substituted, it can be understood that the defined group may be substituted by at least one substituent group R. The substituent group R is selected from, but not limited to, a deuterium atom (D), a cyanoyl group, an isocyanoyl group, a nitro group, a halogen group, a C₁-C₃₀ alkyl group, a heterocyclic group containing 3-20 ring atoms, an aromatic group containing 6-20 ring atoms, a heteroaromatic group containing 5-20 ring atoms, —NR′R″, a silane group, a carbonyl group, an alkoxycarbonyl group, an aryloxycarbonyl group, a carbamoyl group, a haloformyl group, a formyl group, an isocyanate group, a thiocyanate group, an isothiocyanate group, a hydroxyl group, or a trifluoromethyl group. The above-mentioned groups may further be substituted by acceptable substituent groups in the art. Understandably, R′ and R″ in the —NR′R″ are each independently selected from, but not limited to, a hydrogen atom (H), D, a cyanoyl group, an isocyanoyl group, a nitro group, a halogen group, a C₁-C₁₀ alkyl group, a heterocyclic group containing 3-20 ring atoms, an aromatic group containing 6-20 ring atoms, or a heteroaromatic group containing 5-20 ring atoms.

In the present disclosure, “a ring atom number” refers to the number of atoms constituting a ring of a structural compound (such as a monocyclic compound, a fused ring compound, a cross-linked compound, a carbon ring compound, or a heterocyclic compound) obtained by atomic bonding. In a ring substituted by a substituent group, atoms contained in the substituent group are not included in the atoms forming the ring. The same applies to the “number of ring atoms” described below unless otherwise specified. For example, a ring atom number of a benzene ring is 6, a ring atom number of a naphthalene ring is 10, and a ring atom number of a thiophene group is 5. Furthermore, unless otherwise specified, the ring atom is carbon atom.

“Aryl, aryl group, or aromatic group” may be an aryl having a single ring or multiple rings. An aromatic group with a fused ring refers to an aromatic group whose ring may have two or more rings, where two carbon atoms are shared by two adjacent rings, known as the fused ring. The aromatic group is selected from, but not limited to, phenyl, biphenyl, triphenyl, naphthyl, anthracyl, phenanthryl, fluoranthenyl, triphenylene, pyrenyl, perylene, tetraphenyl, fluorenyl, diphenylene, acenaphthenyl, or derivatives thereof.

“Heteroaromatic group” refers to a heteroaromatic hydrocarbon group containing at least one heteroatom. The heteroatom is preferably selected from silicon (Si), nitrogen (N), phosphorus (P), oxygen (O), sulfur (S), and/or germanium (Ge), particularly selected from Si, N, P, O, and/or S. A aromatic group with a fused heterocyclic ring refers to a fused heteroaromatic hydrocarbon group containing at least one heteroatom. For the purpose of the present disclosure, the aromatic group or heteroaromatic group includes not only an aromatic ring system, but also a non-aromatic ring system. For example, pyridine, thiophene, pyrrole, pyrazole, triazole, imidazole, oxazole, oxadiazole, thiazole, tetrazole, pyrazine, pyridazine, pyrimidine, triazine, carbene, or the like, are also considered as aromatic or heteroaromatic groups for the purpose of the present disclosure. For the purpose of the present disclosure, an aromatic system with a fused ring or an aromatic system with a fused heterocyclic ring not only includes systems of aromatic or heteroaromatic groups, but also multiple aromatic or heteroaromatic groups that may be disconnected by short non-aromatic units (for example, a non-hydrogenium atom contenting less than 10% or 5%, such as C, N, or O). Therefore, systems such as 9,9′-spirodifluorene, 9,9-diarylfluorene, triarylamine, diarylether, or the like, should be further included in a definition of the aromatic or heteroaromatic groups.

Examples of the heteroaromatic group include, but are not limited to, a thienyl group, a furanyl group, a pyrrolyl group, an imidazolyl group, a triazolyl group, a diazolyl group, a pyridyl group, a bipyridyl group, a pyrimidinyl group, a triazinyl group, an acridinyl group, a pyridazinyl group, a pyrazinyl group, a quinolinyl group, a quinazolinyl group, a quinoxalinyl group, a phthalazinyl group, a pyridino pyrimidinyl group, a pyridino pyrazinyl group, a pyrazinopyrizinyl group, an isoquinolyl group, an indolyl group, a carbazolyl group, a benzo thienyl group, a benzofuranyl group, a pyrrolo imidazolyl group, a pyrrolo pyrrolyl group, a thiophenopyrrolyl group, a thiophenothiophenyl group, a furanopyrrolyl group, a furanofuranyl group, a thiophenofuranyl group, a benzoisoxazolyl group, a benzoisothiazolyl group, a benzimidazolyl group, an isoquinolinyl group, an o-diazonyl group, a quinoxaline group, a phenanthridinyl group, a primidinyl group, a quinazolinyl group, a quinazolinonyl group, a dibenzothiophenyl group, a dibenzofuranyl group, a carbazolyl group, and derivatives thereof.

In the present disclosure, “alkyl group” refers to a linear alkyl group, a branched alkyl group, or a cyclic alkyl group. A number of carbon atoms in the alkyl group may range from 1 to 50, 1 to 30, 1 to 20, 1 to 10, or 1 to 6. The term “C₁₋₉ alkyl group” refers to an alkyl group containing 1 to 9 carbon atoms. For example, “the C₁₋₉ alkyl group” may be a C₁ alkyl group, a C₂ alkyl group, a C₃ alkyl group, a C₄ alkyl group, a C₅ alkyl group, a C₆ alkyl group, a C₇ alkyl group, a C₈ alkyl group, or a C₉ alkyl group at each occurrence. Examples of the alkyl group include, but are not limited to, methyl, ethyl, n-propyl, iso-propyl, n-butyl, sec-butyl, tert-butyl, iso-butyl, 2-ethylbutyl, 3,3-dimethylbutyl, n-pentyl, iso-pentyl, neopentyl, tert-pentyl, cyclopentyl, 1-methylpentyl, 3-methylpentyl, 2-ethylpentyl, 4-methyl-2-pentyl, n-hexyl, 1-methylhexyl, 2-ethylhexyl, 2-butyl hexyl, cyclohexyl, 4-methylcyclohexyl 4-tert butylcyclohexyl, n-heptyl, 1-methylheptyl, 2,2-dimethylheptyl, 2-ethylheptyl, 2-butyl heptyl, n-octyl, tertoctyl, 2-ethyloctyl, 2-butyl octyl, 2-hexyloctyl, 3,7-dimethyloctyl, cyclooctyl, n-nonyl, n-decyl, adamantine, 2-ethyldecyl, 2-butyl decyl, 2-hexyldecyl, 2-octyldecyl, n-undecyl, n-dodecyl, 2-ethyldodecyl 2-butyl dodecyl, 2-hexyl dodecyl, 2-octyl dodecyl, n-tridecyl, n-tetradecyl, n-pentadecyl, n-hexadecyl, 2-ethyl hexadecyl, 2-butyl hexadecyl, 2-hexyl hexadecyl, 2-octyl hexadecyl, n-heptadecyl, n-octadecyl, n-octadecyl, n-eicosyl, 2-ethyl eicosyl, 2-butyl eicosyl, 2-hexyl eicosyl, 2-octyl eicosyl, twenty one alkyl, twenty two alkyl, twenty three alkyl, twenty four alkyl, twenty five alkyl, twenty six alkyl, twenty seven alkyl, twenty eight alkyl, twenty nine alkyl, thirty alkyl, adamantane, and the like.

In the present disclosure, abbreviations of substituent groups are as follows: normal (n), secondary (sec), iso (i), tertiary (tert), ortho (o), meta (m), para (p), methyl (Me), ethyl (Et), propyl (Pr), butyl (Bu), n-amyl (Am), hexyl (Hx), and cyclohexyl (Cy).

In the present disclosure, “amino group” refers to a derivative of amine, has a feature of a group represented by formula —N(X)₂. X is independently selected from H, a substituted or unsubstituted alkyl group, a substituted or unsubstituted cycloalkyl group, a substituted or unsubstituted heterocyclic group, or the like. Examples of the amino group include, but are not limited to, —NH₂, —N(alkyl)₂, —NH(alkyl), —N(cycloalkyl)₂, —NH(cycloalkyl), —N(heterocyclic)₂, —NH(heterocyclic), —N(aryl)₂, —NH(aryl), —N(alkyl)(aryl), —N(alkyl)(heterocyclic), —N(cycloalkyl)(heterocyclic), —N(aryl)(heteroaryl), —N(alkyl)(heteroaryl), and the like.

In the present disclosure, “*” connected to a single bond indicates a linking site or a fused site.

In the present disclosure, when a linking site in a group is not specified, it means that any of connectable sites in the group may be selected as the linking site.

In the present disclosure, when a fused site in a group is not specified, it means that any of fusible sites in the group may be selected as the fused site. Preferably, two or more adjacent sites in the group are fused sites.

In the embodiments of the present disclosure, the energy level structure of organic materials, including a triplet state energy level ET, a highest occupied molecular orbital (HOMO) energy level, and a lowest unoccupied molecular orbital (LUMO) energy level, plays a crucial role, which will be described in the following.

HOMO and LUMO energy levels can be measured through photoelectric effects, such as X-ray photoelectron spectroscopy (XPS), ultraviolet photoelectron spectroscopy (UPS), or a cyclic voltammetry (CV) method. Recently, quantum chemical methods, such as density functional theory (DFT), have also become effective methods for calculating molecular orbital energy levels.

The triplet state energy level ET1 of the organic materials can be measured through low-temperature time-resolved luminescence spectroscopy, or obtained through quantum simulation calculations (such as through Time-dependent density functional theory (DFT)), or through commercial software Gaussian 03W (Gaussian Inc.). The specific simulation method can refer to patent application WO2011/41110 or described in the following embodiments.

It should be noted that the absolute values of HOMO, LUMO, and ET1 depend on the measurement or calculation method used, and even for the same method, different evaluation methods, such as starting and peak points on the CV curve, may give different HOMO or LUMO values. Therefore, reasonable and meaningful comparisons should be made using the same measurement methods and evaluation methods. In the description of the embodiments of the present disclosure, the values of HOMO, LUMO, and ET1 are based on simulation of the Time-dependent DFT, but do not affect the application of other measurement or calculation methods.

In the invention, (HOMO−1) is defined as a second highest occupied orbital energy level, (HOMO−2) is defined as a third highest occupied orbital energy level, and the like. (LUMO+1) is defined as a second lowest unoccupied orbital energy level, and (LUMO+2) is defined as a third lowest occupied orbital energy level, and the like.

The present disclosure provides an organic boron-nitrogen compound, which has a structure represented by Formula (I):

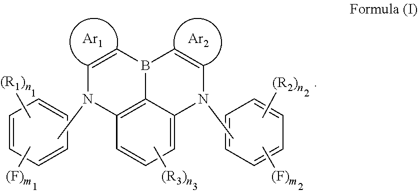

In the formula (I), Ar₁ is represented by the following formula:

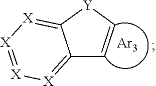

and

Ar₂ is represented by any one of the following formulas:

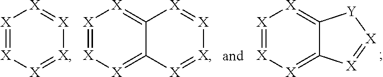

X is independently selected from CR₄ or N at each occurrence, and X is C when X is at a fused site;

Y is independently selected from CR₅R₆, NR₇, S, or O at each occurrence ;

R₁-R₇ are each independently selected from H, D, a C₁₋₂₀ linear alkyl group, a C₁₋₂₀ linear alkoxyl group, a C₁₋₂₀ linear thioalkoxyl group, a C₃₋₂₀ branched alkyl group, a C₂₋₂₀ cycloalkyl group, a C₃₋₂₀ branched alkoxyl group, a C₂₋₂₀ cycloalkoxy group, a C₃₋₂₀ branched thioalkoxyl group, a C₂₋₂₀ thiocycloalkoxy group, a methylsilyl group, a ketone group, an alkoxycarbonyl group, an aryloxycarbonyl group, a substituted or unsubstituted aromatic group containing 6-40 ring atoms, a substituted or unsubstituted heteroaromatic group containing 5-40 ring atom, a substituted or unsubstituted aryloxy group containing 6-40 ring atoms, a substituted or unsubstituted heteroaryloxy group containing 5-40 ring atoms, a cyanoyl group, a carbamoyl group, a haloformyl group, a formyl group, an isocyano group, an isocyanate group, a thiocyanate group, an isothiocyanate group, a hydroxyl group, a nitro group, an amino group, CF₃, Cl, Br, F, I, or combinations thereof at each occurrence;

n₁, n₂, and n₃ are each independently selected from 0, 1, 2, or 3, m₁ and m₂ are each independently selected from 0, 1, or 2, and at least one of m₁ and m₂ is not 0; and

Ar₃ is selected from a substituted or unsubstituted aromatic group containing 6-40 carbon atoms or a substituted or unsubstituted heteroaromatic group containing 6-40 ring atoms.

In some embodiments, Ar₁ is selected from any one of the following groups:

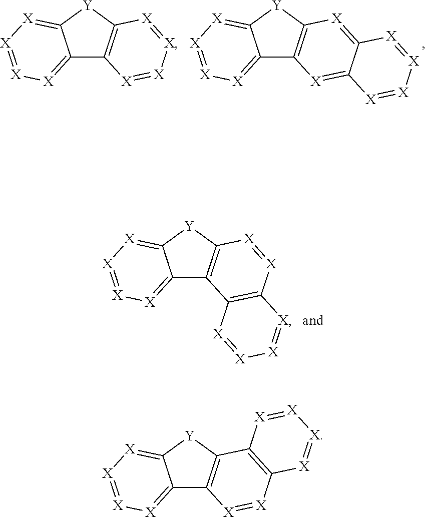

In some embodiments, Ar₁ is selected from any one of the following groups:

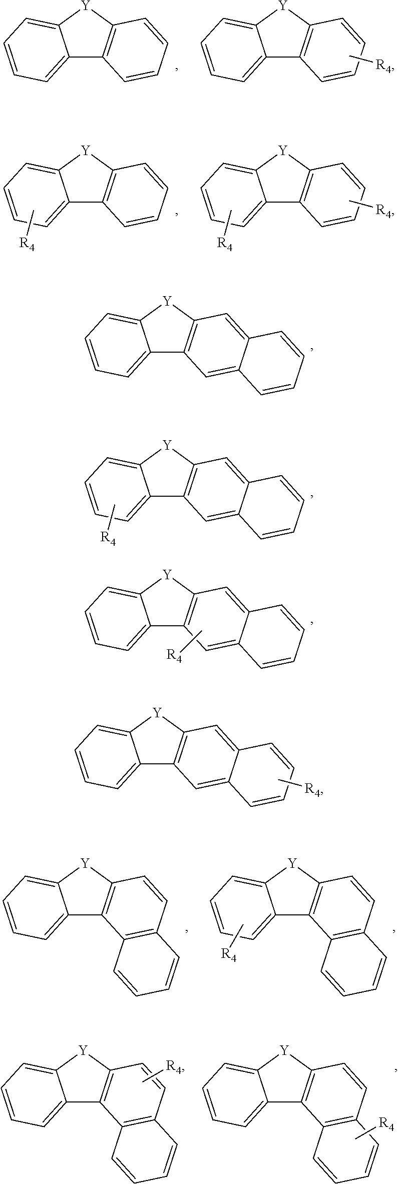

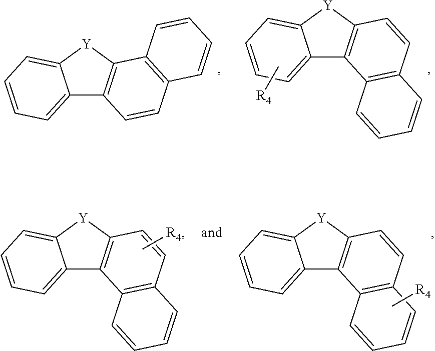

in which R₄ and Y are defined as above.

In some embodiments, Y is selected from any one of O, S, and the following groups:

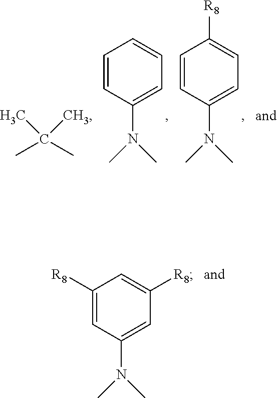

R₄ and R₈ are each independently selected from methyl, ethyl, n-propyl, iso-propyl, n-butyl, iso-butyl, tert-butyl, tert-amyl, or phenyl.

In some embodiments, Ar₂ is selected from any one of the following groups:

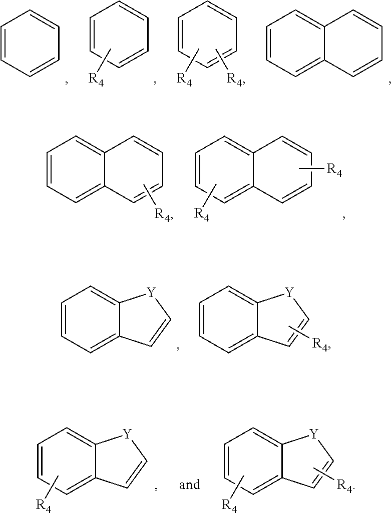

In some embodiments. the organic boron-nitrogen compound is selected from any one of Formula (I-1) to Formula (I-9):

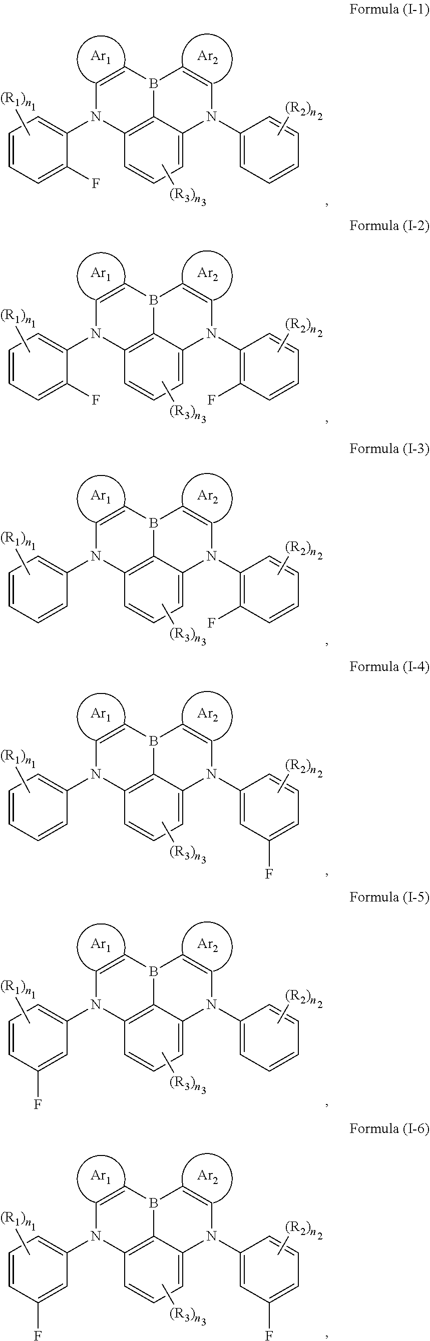

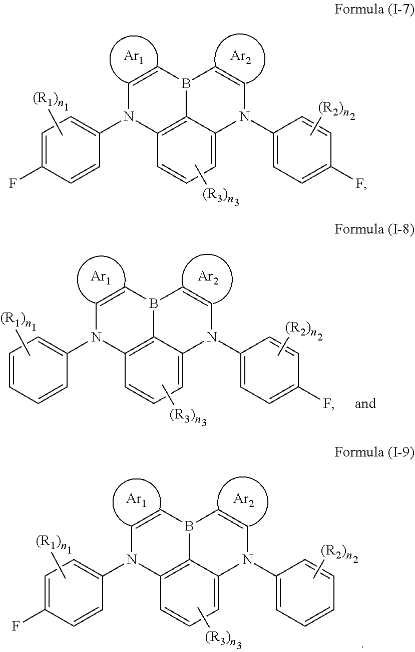

In some embodiments, n₁, n₂, and n₃ are each independently selected from 0 or 1, and at least one of n₁, n₂, and n₃ is not 0.

In some embodiments, R₁-R₇ are each independently selected from methyl, ethyl, n-propyl, iso-propyl, n-butyl, iso-butyl, tert-butyl, tert-amyl, or phenyl.

In some embodiments, the organic boron-nitrogen compound is selected from any one having the following structures:

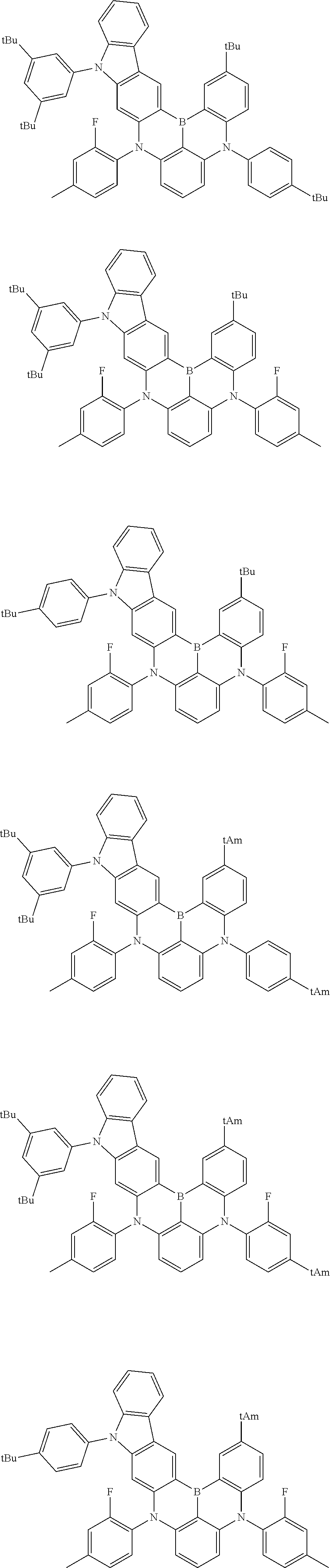

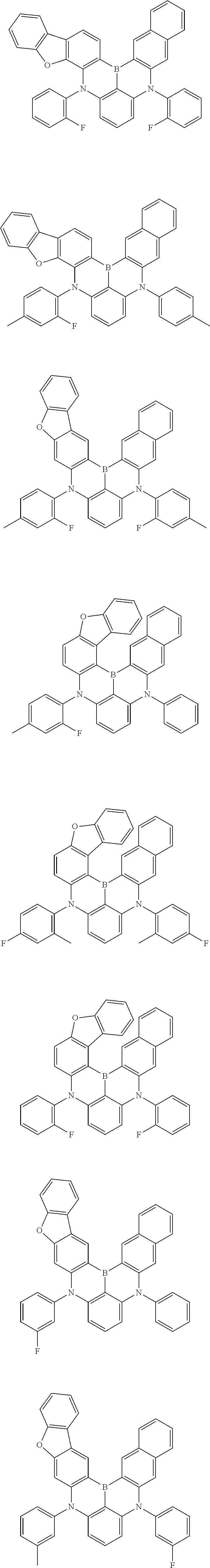

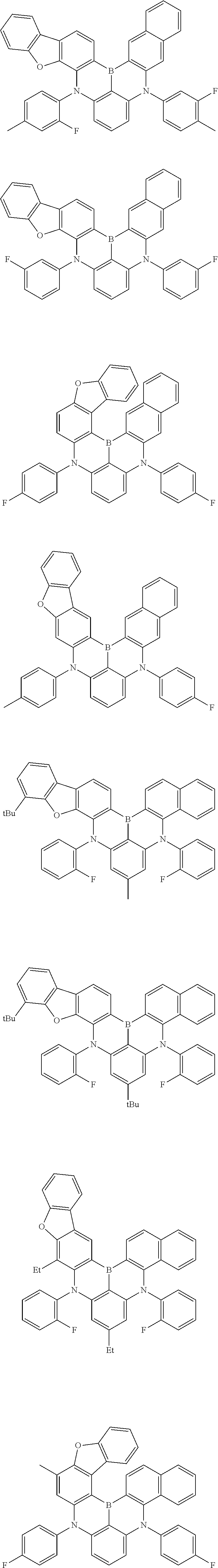

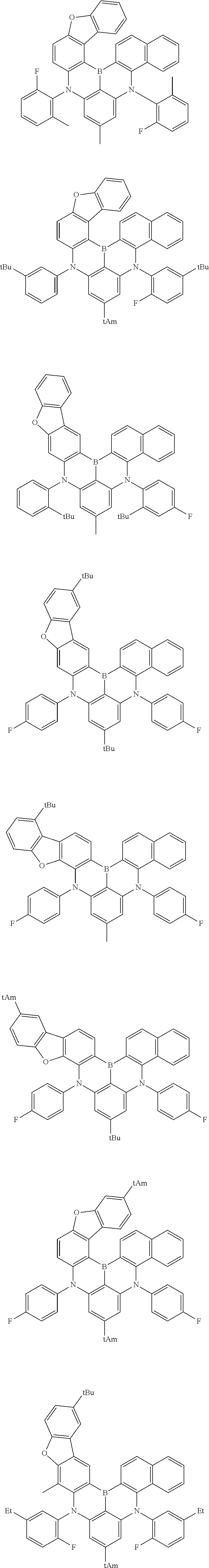

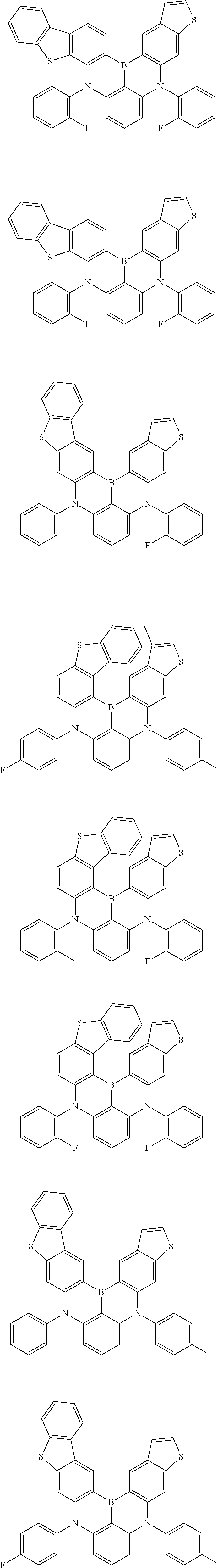

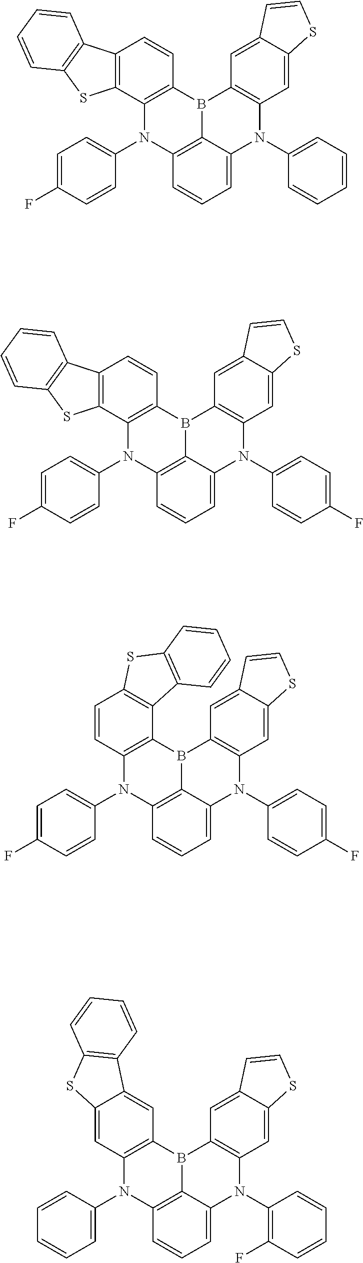 [SMILES: Fc1ccc(N2c3cccc4c3B(c3cc5ccsc5cc3N4c3ccccc3)c3ccc4c(sc5ccccc54)c32)cc1 ; Fc1ccc(N2c3cc4sccc4cc3B3c4ccc5c(sc6ccccc65)c4N(c4ccc(F)cc4)c4cccc2c43)cc1 ; Fc1ccc(N2c3cc4sccc4cc3B3c4c2cccc4N(c2ccc(F)cc2)c2ccc4sc5ccccc5c4c23)cc1 ; Fc1ccccc1N1c2cc3sccc3cc2B2c3cc4c(cc3N(c3ccccc3)c3cccc1c32)sc1ccccc14]

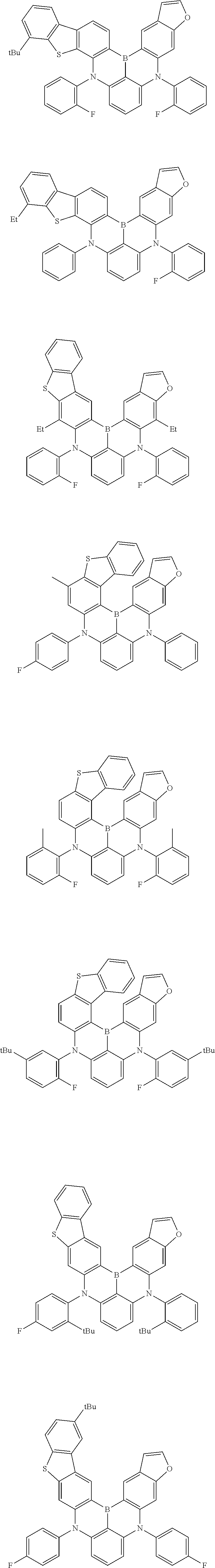

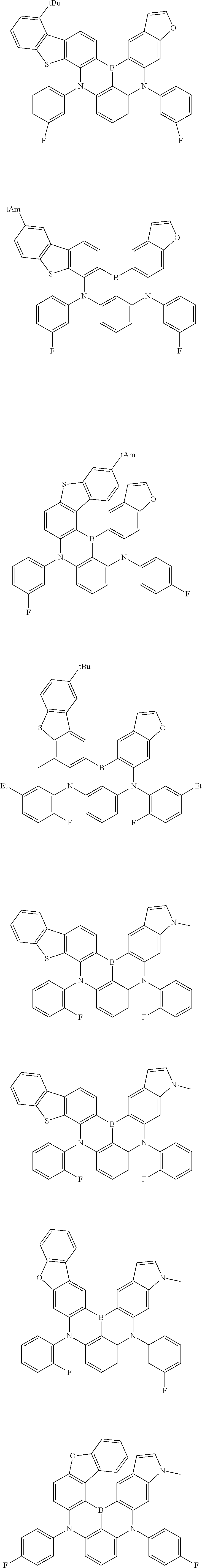

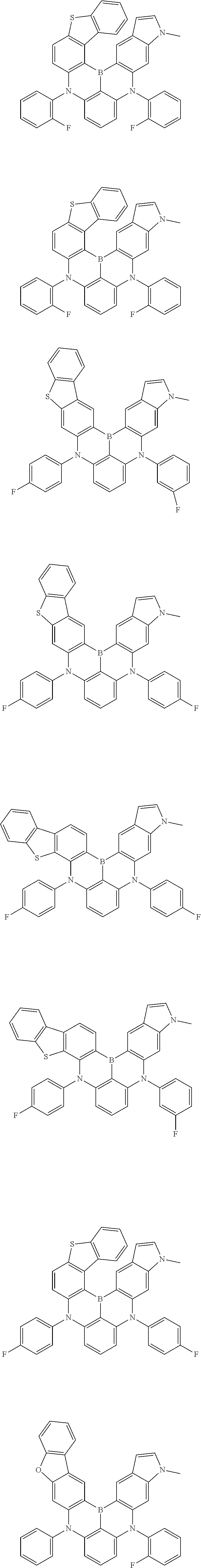

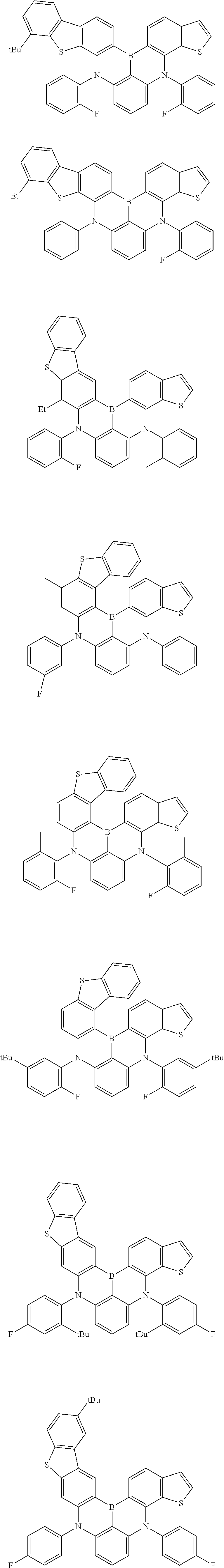

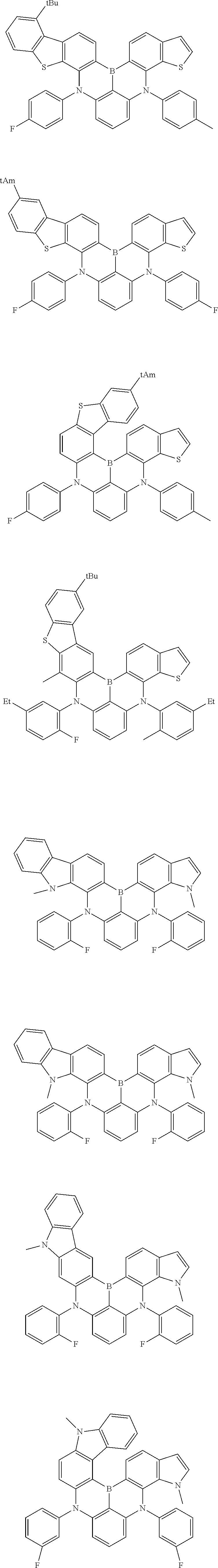

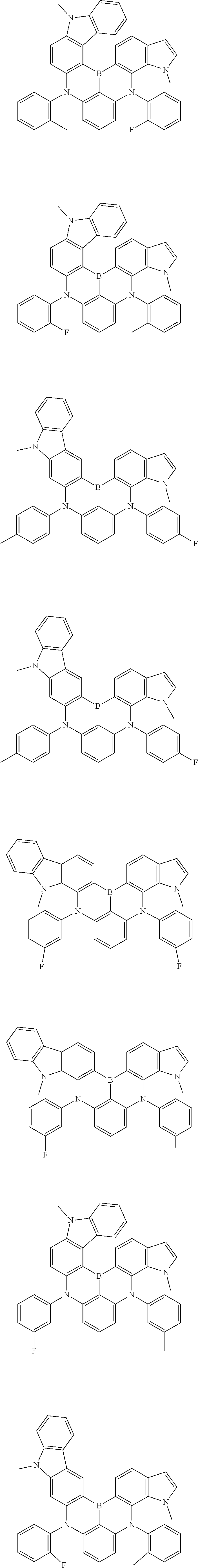

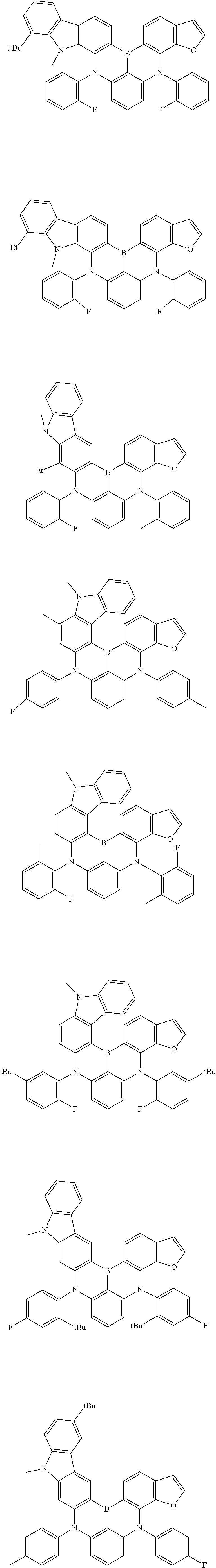

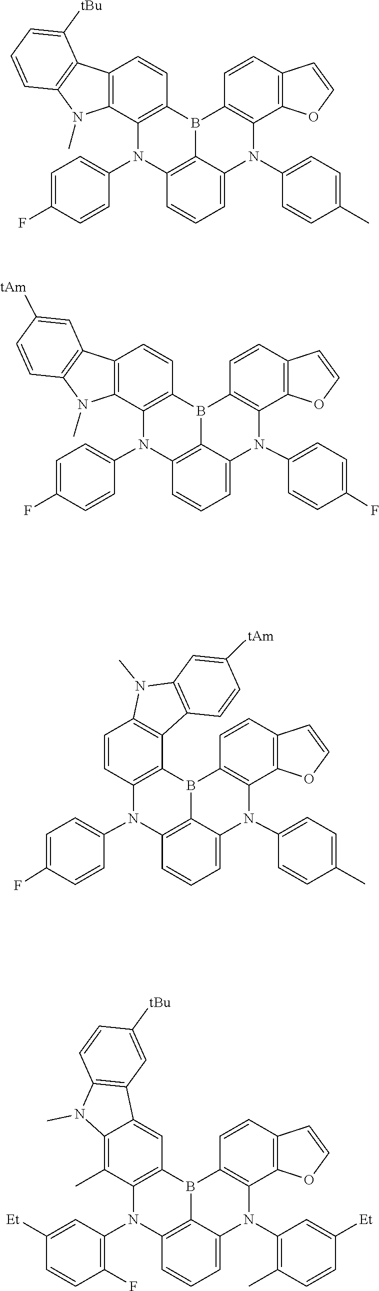

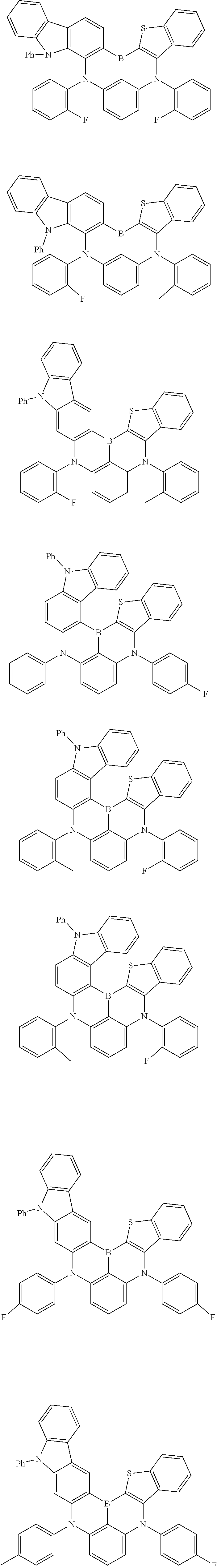

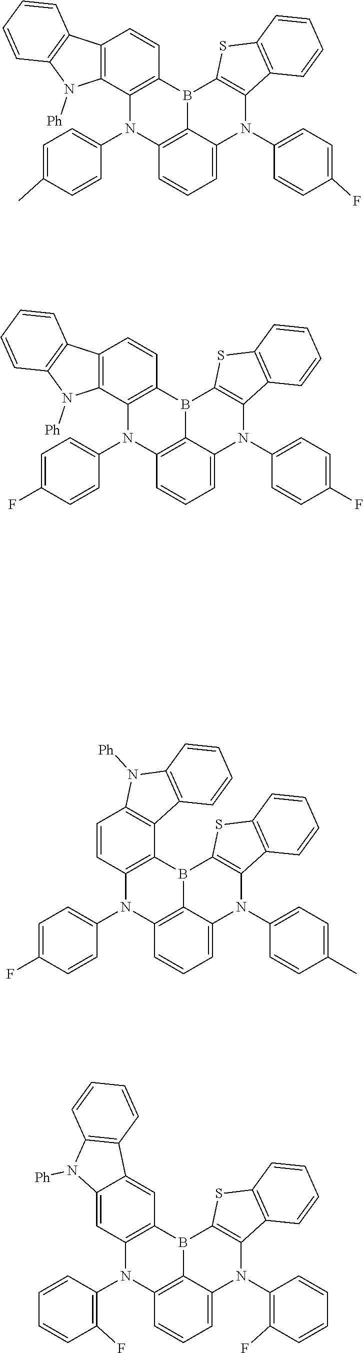 [SMILES: Cc1ccc(N2c3cccc4c3B(c3ccc5c6ccccc6n(-c6ccccc6)c5c32)c2sc3ccccc3c2N4c2ccc(F)cc2)cc1 ; Fc1ccc(N2c3cccc4c3B(c3ccc5c6ccccc6n(-c6ccccc6)c5c3N4c3ccc(F)cc3)c3sc4ccccc4c32)cc1 ; Cc1ccc(N2c3cccc4c3B(c3sc5ccccc5c32)c2c(ccc3c2c2ccccc2n3-c2ccccc2)N4c2ccc(F)cc2)cc1 ; Fc1ccccc1N1c2cc3c(cc2B2c4sc5ccccc5c4N(c4ccccc4F)c4cccc1c42)c1ccccc1n3-c1ccccc1]

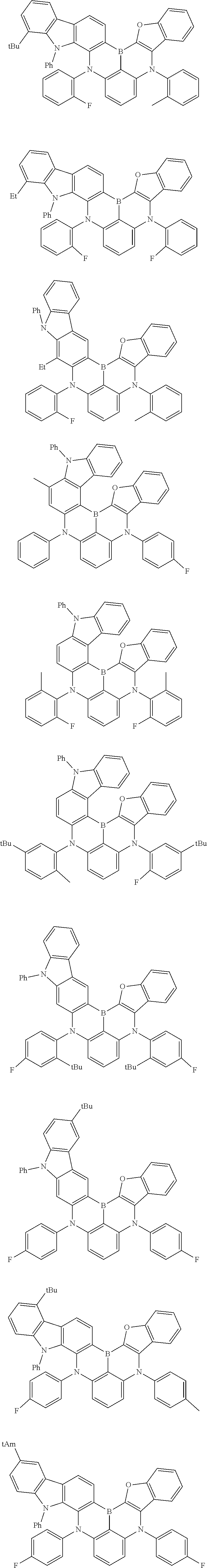

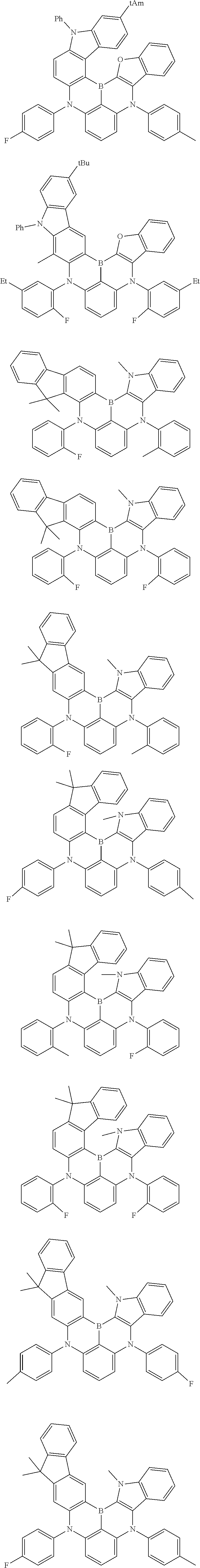

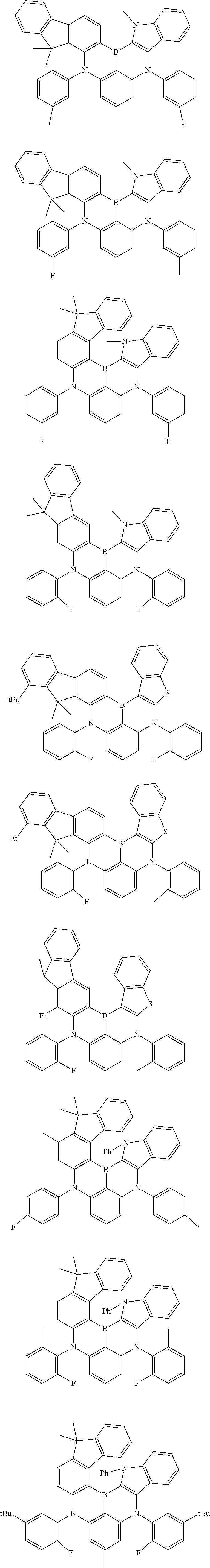

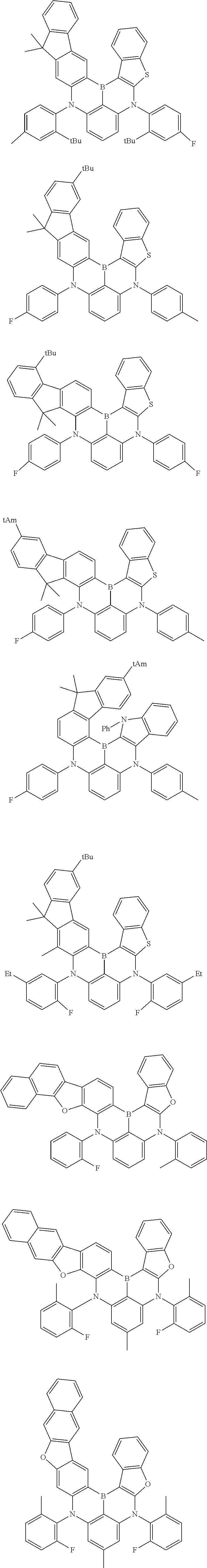

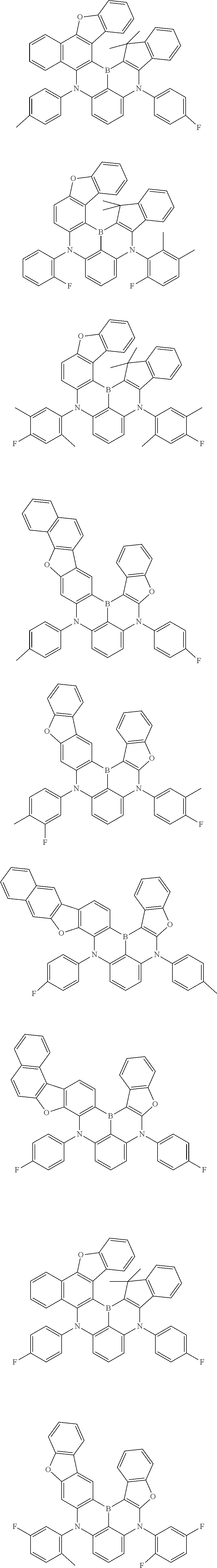

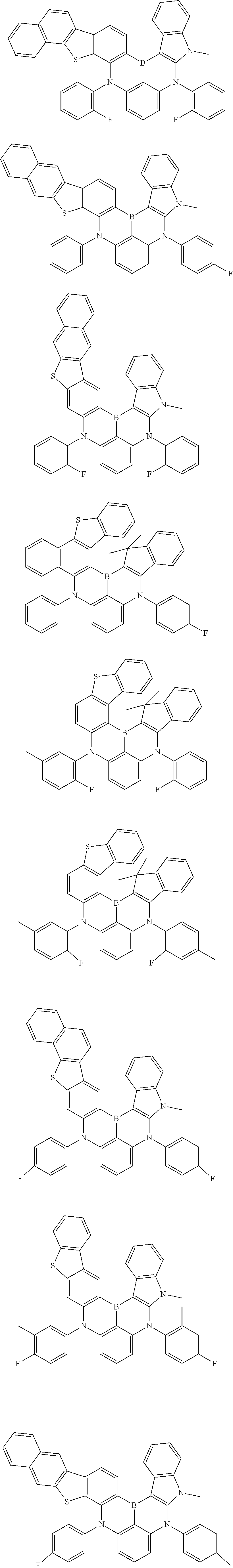

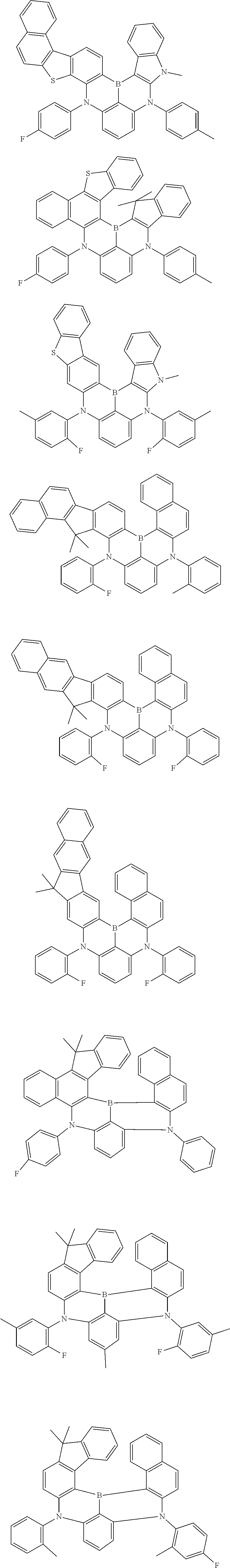

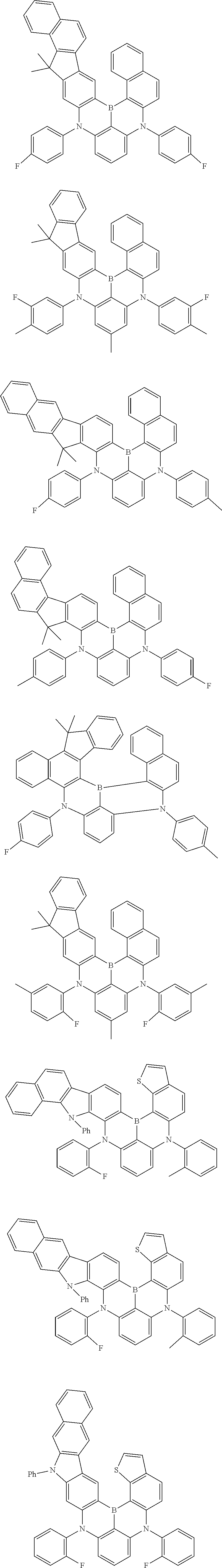

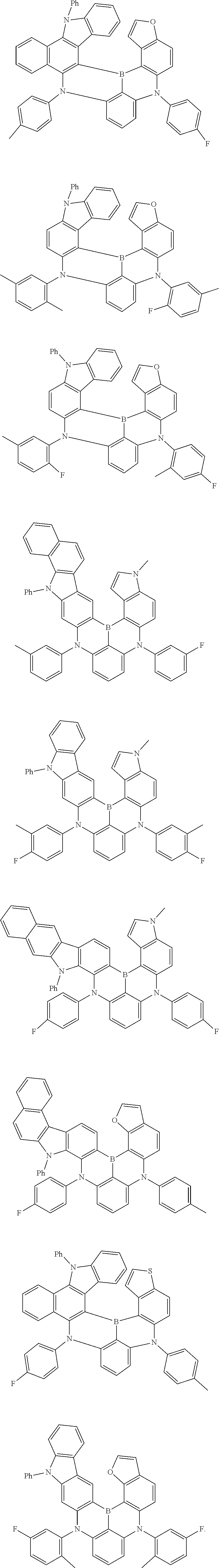

Embodiments of the present disclosure further provide a mixture including the organic boron-nitrogen compound provided in the above-mentioned embodiments and at least one organic functional material. The organic functional material is selected from a hole injection material, a hole transport material, an electron transport material, an electron injection material, an electron blocking material, a hole blocking material, an emitter, a host material, or an organic dye. The emitter is selected from an organic thermally excited delayed fluorescence (TADF) material having a singlet state (such as a fluorescent emitter) or a triplet state (such as a phosphorescent emitter). Detailed description of various organic functional materials can refer to applications WO2010135519A1, US20090134784A1, and WO2011110277A1. All contents of these three applications are hereby incorporated as a reference in the context. In some embodiments, the organic functional material may be small molecule material or high polymer.

In some embodiments, another organic functional material may be a host material. Further, the above-mentioned another organic functional material is a blue light host material.

Embodiments of the present disclosure further provide a composition, which includes the organic boron-nitrogen compound or the mixture as described above, and at least one organic solvent.

The composition may be ink. When the ink is used in a printing process, the viscosity and surface tension of the ink are important parameters. The appropriate surface tension of the ink is suitable for a specific substrate and a specific printing method.

In some embodiments, the surface tension of the ink at an operation temperature or a temperature of 25° C. according to the present disclosure ranges from approximately 19 dyne/cm to 50 dyne/cm, 22 dyne/cm to 35 dyne/cm, or 25 dyne/cm to 33 dyne/cm.

In some embodiments, the viscosity of the ink at an operation temperature or a temperature of 25° C. according to the present disclosure ranges from 1 cps to 100 cps, 1 cps to 50 cps, 1.5 cps to 20 cps, or 4.0 cps to 20 cps. The ink prepared using the above-mentioned parameters is beneficial for inkjet printing.

The viscosity of the ink can be adjusted through different methods, such as selecting appropriate solvents or adjusting the concentration of a functional material in the ink. The ink containing the organic boron-nitrogen compound according to the present disclosure is beneficial for adjusting the ink within an appropriate range based on the used printing method. Generally, a weight percentage of the functional materials in the composition according to the present disclosure ranges from 0.3 wt % to 30 wt %, 0.5 wt % to 20 wt %, 0.5 wt % to 15 wt %, 0.5 wt % to 10 wt %, or 1 wt % to 5 wt %.

In some embodiments, at least one organic solvent in the composition is selected from an aromatic-based solvent, an heteroaromatic-based solvent, an ester-based solvent, an aromatic ketone-based solvent, an aromatic ether-based solvent, an aliphatic ketone-based solvent, an aliphatic ether-based solvent, an alicyclic compound, an olefin compound, a borate ester compound, a phosphate ester compound, or a mixture of at least two of the above-mentioned solvents.

In some embodiments, at least one organic solvent in the composition according to the present disclosure is selected from an aromatic-based or heteroaromatic-based solvent.

Examples of the aromatic-based solvent or the heteroaromatic-based solvent suitable for the present disclosure include, but are not limited to, p-diisopropylbenzene, pentyl benzene, tetrahydronaphthalene, cyclohexylbenzene, chloronaphthalene, 1,4-dimethylnaphthalene, 3-isopropylbiphenyl, p-methylisopropyl benzene, dipentyl benzene, tripentyl benzene, pentyl toluene, o-diethylbenzene, m-diethylbenzene, p-diethylbenzene, 1,2,3,4-tetratoluene, 1,2,3,5-tetratoluene, 1,2,4,5-tetratoluene, butyl benzene, dodecylbenzene, dihexylbenzene, dibutylbenzene, p-diisopropylbenzene, cyclohexylbenzene, benzylbutylbenzene, dimethylnaphthalene, 3-isopropylbiphenyl, p-methylcumene, 1-methylnaphthalene, 1,2,4-trichlorobenzene, 4,4-difluorodiphenylmethane, 1,2-dimethoxy-4-(1-propenyl) benzene, diphenylmethane, 2-phenylpyridine, 3-phenylpyridine, N-methyldiphenylamine, 4-isopropylbiphenyl, a, a-dichlorodiphenylmethane, 4-(3-phenylpropyl) pyridine, benzyl benzoate, 1,1-bis(3,4-dimethylphenyl) ethane, 2-isopropylnaphthalene, quinoline, isoquinoline, methyl 2-furanoate, ethyl 2-furanoate, and the like.

Examples of the aromatic ketone-based solvent suitable for the present disclosure include, but are not limited to, 1-tetrahydronaphthalenone, 2-tetrahydronaphthalenone, 2-(phenyl epoxy) tetrahydronaphthalenone, 6-(methoxyl) tetrahydronaphthalenone, acetophenone, phenylacetone, benzophenone, and derivatives of these compounds. For example, the above-mentioned derivatives may be selected from at least one of 4-methylacetophenone, 3-methylacetophenone, 2-methylacetophenone, 4-methylphenylacetone, 3-methylphenylacetone, 2-methylphenylacetone, and the like.

Examples of the aromatic ether-based solvent suitable for the present disclosure include, but are not limited to, 3-phenoxytoluene, butoxybenzene, p-anisaldehyde dimethyl acetal, tetrahydro-2-phenoxy-2H-pyran, 1.2-dimethoxy-4-(1-propenyl)benzene, 1,4-benzodioxane, 1,3-dipropylbenzene, 2,5-dimethoxytoluene, 4-ethylbasic ether, 1,3-dipropoxybenzene, 1,2,4-trimethoxybenzene, 4-(1-propenyl)-1,2-dimethoxybenzene, 1,3-dimethoxybenzene, glycidyl phenyl ether, dibenzyl ether, 4-tert-butyl anisole, trans-p-propenylanisole, 1,2-dimethoxybenzene, 1-methoxynaphthalene, diphenyl ether, 2-phenoxymethyl ether, 2-phenoxytetrahydrofuran, and ethyl-2-naphthyl ether.

In some embodiments, at least one solvent in the composition according to the present disclosure is selected from the aliphatic ketone-based solvent, such as 2-nonone, 3-nonone, 5-nonone, 2-decanone, 2,5-hexanedione, 2,6,8-trimethyl-4-nonone, fenone, phorone, isophorone, di-n-pentyl ketone, or the like.

In some embodiments, at least one solvent in the composition according to the present disclosure is selected from the aliphatic ether-based solvent, such as amyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethylene glycol ethyl methyl ether, triethylene glycol butyl methyl ether, tripropylene glycol dimethyl ether, tetraethylene glycol dimethyl ether, or the like.

In some embodiments, at least one solvent in the composition according to the present disclosure is selected from the ester-based solvent, such as octanoate, sebacate, stearate, benzoate, phenylacetate, cinnamate, oxalate, maleate, alkyl lactone, oleate, and the like. Preferably, the ester-based solvent may be selected from at least one of octyl octanoate, diethyl sebacate, diallyl phthalate, or isononyl isononanoate.

The above-mentioned organic solvent can be used individually or used as a mixture of two or more organic solvents.

In some embodiments, examples of another organic solvent are selected from, but not limited to, methanol, ethanol, 2-methoxyethanol, dichloromethane, chloroform, chlorobenzene, o-dichlorobenzene, tetrahydrofuran, anisole, morpholine, toluene, o-xylene, m-xylene, p-xylene, 1,4-dioxane, acetone, methyl ethyl ketone, 1,2-dichloroethane, 3-phenoxytoluene, 1,1,1-trichloroethane, 1,1,2,2-tetrachloroethane, ethyl acetate, butyl acetate, dimethylformamide, dimethylacetamide, dimethyl sulfoxide, tetralin, naphthane, indene, and mixtures thereof.

In some embodiments, a solvent particularly suitable for the present disclosure is a solvent having a Hansen solubility parameter within the following ranges:
a dispersion force (δd) ranging from 17.0 MPa^{1/2} to 23.2 MPa^{1/2}, especially from 18.5 MPa^{1/2} to 21.0 MPa^{1/2};
a polarity force (SP) ranging from 0.2 MPa^{1/2} to 12.5 MPa^{1/2}, especially from 2.0 MPa^{1/2} to 6.0 MPa^{1/2}; and
a hydrogen bonding force (δh) ranging from 0.9 MPa^{1/2} to 14.2 MPa^{1/2}, especially from 2.0 MPa^{1/2} to 6.0 MPa^{1/2}.

For the composition according to the present disclosure, a boiling point needs to be considered when selecting the organic solvent. In some embodiments, the boiling point of the organic solvent is greater than or equal to 150° C., 180° C., 200° C., 250° C., or 300° C. The boiling point within any of these ranges is beneficial to prevent nozzles of inkjet printing heads from clogging. The organic solvent can be evaporated from a solvent system to form a film including the functional material.

In some embodiments, the composition according to some embodiments of the present disclosure may be a solution.

In some embodiments, the composition according to some embodiments of the present disclosure may be a suspension.

The composition in the embodiments of the present disclosure may include 0.01 wt % to 10 wt % of the compound or the mixture according to the present disclosure, preferably 0.1 wt % to 5 wt %, preferably 0.2 wt % to 5 wt %, more preferably 0.25 wt % to 3 wt %.

The present disclosure further provides an application of the composition as a coating material or printing ink in the preparation for an organic electronic device, preferably a preparation method of printing or coating.

Methods suitable for printing or coating include, but are not limited to, inkjet printing, nozzle printing, letterpress printing, screen printing, dip coating, rotary coating, scraper coating, roller printing, torsion roller printing, lithographic printing, flexographic printing, rotary printing, spraying, brushing or pad printing, slit extrusion coating, or the like. Gravure printing, jet printing and inkjet printing are preferred. The solution or suspension may additionally include one or more components such as surfactant compounds, lubricants, wetting agents, dispersants, hydrophobic agents, adhesives, or the like, for adjusting viscosity, film-forming properties, improving adhesion, or the like. Requirements for parameters in relevant printing technology, such as a solvent, concentration, viscosity, or the like, should be considered.

The present disclosure further provides an application of the above-mentioned organic boron-nitrogen compound, the mixture, or the composition in an organic electronic device, which can be selected from, but not limited to, an organic light-emitting diode (OLED), an organic photovoltaic battery (OPV), an organic light-emitting battery (OLEEC), an organic field-effect tube (OFET), an organic light-emitting field-effect tube, an organic laser, an organic spin electron device, an organic sensor, an organic plasmon emission diode (OPED), or the like. The organic electronic device is preferably the OLED.

Embodiments of the present disclosure further provide an organic electronic device, which includes a cathode and an anode disposed opposite to each other, and an organic functional layer disposed between the cathode and the anode. A material of the organic functional layer includes the above-mentioned organic boron-nitrogen compound or the mixture, or is prepared from the above-mentioned composition.

In some embodiments, the organic electronic device is selected from, but not limited to, an OLED, an OPV, an OLEEC, an OFET, an organic light-emitting field-effect tube, an organic laser, an organic spin electron device, an organic sensor, an OPED, or the like.

In some embodiments, the organic electronic device is an organic light-emitting diode, and the organic functional layer includes a hole injection layer, a hole transport layer, a light-emitting layer, an electron blocking layer, an electron injection layer, an electron transport layer, a hole blocking layer, and a charge generation layer.

In some embodiments, materials of the light-emitting layer include a light-emitting host material and a light-emitting guest material, and the light-emitting guest material includes the above-mentioned organic boron-nitrogen compound or the mixture, or is prepared from the above-mentioned composition.

In some embodiments, the organic electronic device further includes a substrate disposed on one side of the cathode or the anode. The substrate can be opaque or transparent, and used to manufacture a transparent light-emitting component. Detailed description about the substrate can refer to Bulovic et al. (Nature 1996, 380, p29), and Gu et al. (Appl Phys Lett 1996, 68, p2606). The substrate may be rigid or flexible. Specifically, the substrate may be plastic, metal, a semiconductor chip, or a glass. It is best for the substrate to have a smooth surface. A substrate without surface defects is a particularly ideal choice. In some embodiments, the substrate may be flexible, and a material of the substrate may be selected from but not limited to a polymer film or plastic. A glass transition temperature Tg of a material of the substrate may be greater than 150° C. 200°° C., 250° C., or 300° C. Examples of materials of a suitable flexible substrate include polyethylene terephthalate (PET) and polyethylene naphthalene-2,6-dicarboxylate (PEN).

In some embodiments, a material of the anode may include conductive metal, conductive metal oxide, or conductive polymer. The anode can be easily injected into a hole injection layer (HIL), a hole transport layer (HTL), or the light-emitting layer. In some embodiments, absolute value of a difference between work function of the anode and HOMO energy level or valence band energy level of a light-emitting material of the light-emitting layer, or a p-type semiconductor material of the HIL, the HTL, or an electron blocking layer (EBL) is less than 0.5 eV, preferably 0.3 eV, more preferably 0.2 eV. Examples of the material of the anode include, but are not limited to, aluminum (Al), copper (Cu), aurum (Au), argentum (Ag), magnesium (Mg), ferrum (Fe), cobalt (Co), nickel (Ni), manganese (Mn), palladium (Pd), platinum (Pt), indium tin oxide (ITO), aluminum doped zinc oxide (AZO), and the like. Other suitable materials are known, and an ordinary in the art can easily choose to use. The material of the anode may be applied to any suitable technology, such as a suitable physical vapor deposition method, including RF magnetron sputtering, vacuum thermal evaporation, electron beam (e-beam), or the like. In some embodiments, the anode is a patterned structure. A patterned ITO conductive substrate is commercially available and can be used to prepare the organic electronic device according to the present disclosure.

In some embodiments, the cathode may include a conductive metal or a conductive metal oxide. The cathode can be easily injected into an electron injection layer (EIL), an electron transport layer (ETL), or the light-emitting layer. In an embodiment, absolute value of a difference between work function of the cathode and LUMO energy level or valence band energy level of the light-emitting material of the light-emitting layer, or a n-type semiconductor material of the EIL, the ETL, or a hole blocking layer (HBL) is less than 0.5 eV, preferably 0.3 eV, more preferably 0.2 eV. In principle, all materials that can be used for the cathode of an organic electronic device may be used as the material of the cathode of the device according to the present disclosure. Examples of the material of the cathode include, but are not limited to, Al, Au, Ag, calcium (Ca), barium (Ba), Mg, LiF/Al, MgAg alloy, BaF₂/Al, Cu, Fe, Co, Ni, Mn, Pd, Pt, ITO, and the like. The material of the cathode may be applied to by any suitable technology, such as a suitable physical vapor deposition method including RF magnetron sputtering, vacuum thermal evaporation, electron beam (e-beam), or the like.

In some embodiments, the materials of the hole injection layer, the hole transport layer, the electron blocking layer, the electron injection layer, the electron transport layer, the hole blocking layer, and the charge generation layer are conventional materials in the art. The materials suitable for use in these functional layers have been described in detail above and can also refer to patent applications WO2010/135519A1, US2009/0134784A1, and WO2011/110277A1. All the contents of these three patent applications are hereby incorporated as a reference in this context.

An emission wavelength of the organic electronic device according to the present disclosure ranges from 300 nm to 1000 nm, 350 nm to 900 nm, or 400 nm to 800 nm.

Embodiments of the present disclosure further provide an electronic apparatus, which includes the above-mentioned organic electronic device.

In some embodiments, the electronic apparatus includes, but is not limited to, a display device, an illumination device, a light source, a sensor, or the like.

The following provides a further detailed description of the organic boron-nitrogen compound of the present disclosure in conjunction with specific examples. The raw materials used in the following examples, unless otherwise specified, are all commercially available products.

### Example 1

Synthetic Route of Compound 1 is as follows:

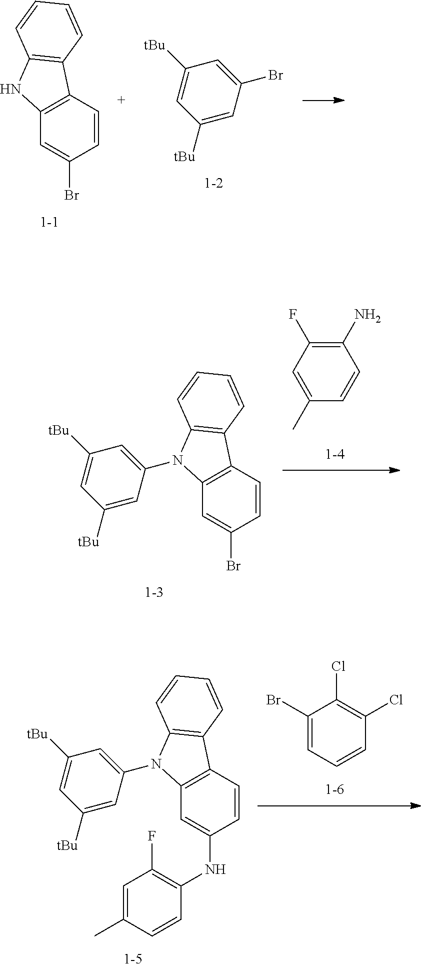

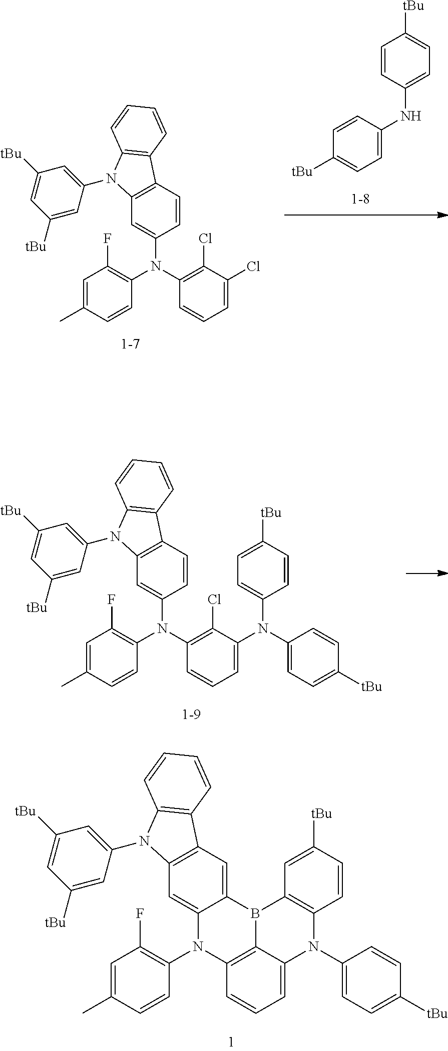 [SMILES: Cc1ccc(N(c2ccc3c4ccccc4n(-c4cc(C(C)(C)C)cc(C(C)(C)C)c4)c3c2)c2cccc(Cl)c2Cl)c(F)c1 ; CC(C)(C)c1ccc(Nc2ccc(C(C)(C)C)cc2)cc1 ; Cc1ccc(N(c2ccc3c4ccccc4n(-c4cc(C(C)(C)C)cc(C(C)(C)C)c4)c3c2)c2cccc(N(c3ccc(C(C)(C)C)cc3)c3ccc(C(C)(C)C)cc3)c2Cl)c(F)c1 ; Cc1ccc(N2c3cc4c(cc3B3c5cc(C(C)(C)C)ccc5N(c5ccc(C(C)(C)C)cc5)c5cccc2c53)c2ccccc2n4-c2cc(C(C)(C)C)cc(C(C)(C)C)c2)c(F)c1]

Synthetic Steps of Compound 1 are as follows:

### 1) Synthesis of Intermediate 1-3

Compound 1-1 (10 mmol), compound 1-2 (10 mmol), CuI (10 mmol), and tripotassium phosphate (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 1-3 (7.83 mmol) with yield of 78.3%. A result of atmospheric solids analysis probe-mass spectrometry (ASAP-MS) of the intermediate 1-3 was as follows: MS (ASAP)=433.

### 2) Synthesis of Intermediate 1-5

Compound 1-3 (10 mmol), compound 1-4 (10 mmol), bis(di tert-butyl-4-dimethylamino phenylphosphine)palladium chloride (Pd-132, 0.1 mmol), 2-dicyclohexylphosphine-2′,6′-dimethoxyl-1,1′-biphenyl (SPhos, 0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 1-5 (6.11 mmol) with yield of 61.1%. MS (ASAP)=478.

### 3) Synthesis of Intermediate 1-7

Compound 1-5 (10 mmol), compound 1-6 (10 mmol), palladium bis dibenzylideneacetone (Pd(dba)₂, 0.1 mmol), tri-tert-butylphosphine (TTBP, 0.2 mmol), and sodium tert-butoxide (30 mmol) were dissolved in toluene, and stirred for 6 hours at a temperature of 100°° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 1-7 (8.18 mmol) with yield of 81.8%. MS (ASAP)=622.

### 4) Synthesis of Intermediate 1-9

Compound 1-7 (10 mmol), compound 1-8 (10 mmol), Pd(dba)₂ (0.1 mmol), TTBP (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 1-9 (6.87 mmol) with yield of 68.7%. MS (ASAP)-867.

### 5) Synthesis of Compound 1

The intermediate 1-9 (10 mmol) and dried tert-butyl benzene (100 mL) were added into a three necked-flask (250 mL), and cooled to a temperature of 30° C. in a nitrogen atmosphere. n-hexane solution containing tert-butyllithium (t-BuLi, 21 mmol) was added into the solution dropwise. Raise the temperature of the solution to 60° C., then the solution was reacted for 2 hours. After the reaction was completed, n-hexane was removed from the reaction solution by rotary evaporation. Then the reaction solution was cooled again to a temperature of 30° C., and boron tribromide solution (21 mmol) was added. Raise the temperature to room temperature, and the reaction solution was stirred for 0.5 hour. Subsequently, the reaction solution was cooled to a temperature of 0° C., and N,N-diisopropylethylamine (42 mmol) was added dropwise. After the dropping was completed, raise the temperature to room temperature under a stirring state. Continue to raise the temperature to 120° C., the reaction solution was stirred for 3 hours, and then cooled to room temperature. Sodium carbonate aqueous solution and ethyl acetate were added into the reaction solution to quench the reaction. The aqueous phase was extracted with ethyl acetate and the organic phases were merged, and the solvent was removed by rotary evaporation to obtain a crude product. Then the crude product was purified by column chromatography to obtain a pure product. Finally, the pure product was further purified by recrystallization using toluene and ethyl acetate as solvents, to obtain a light yellow solid powder that was the compound 1 with yield of 47.2%. MS=841.

### Example 2

Synthetic Route of Compound 2 is as follows:

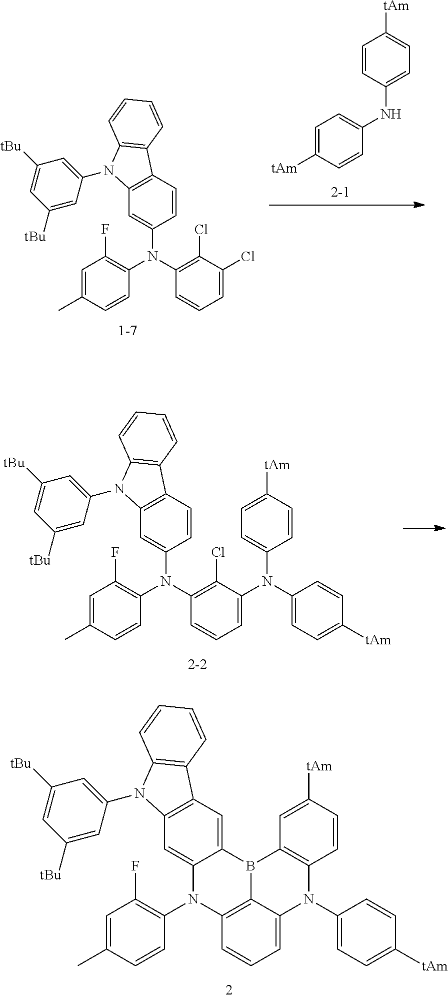

Synthetic Steps of Compound 2 are as follows:

### 1) Synthesis of Intermediate 2-2

Compound 1-7 (10 mmol), compound 2-1 (10 mmol), Pd(dba)₂ (0.1 mmol), TTBP (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 2-2 (5.79 mmol) with yield of 57.9%. MS (ASAP)=895.

### 2) Synthesis of Compound 2

The intermediate 2-2 (10 mmol) and dried tert-butyl benzene (100 mL) were added into a three necked-flask (250 mL), and cooled to a temperature of 30° C. in a nitrogen atmosphere. n-hexane solution containing tert-butyllithium (t-BuLi, 21 mmol) was added into the solution dropwise. Raise the temperature of the solution to 60° C., then the solution was reacted for 2 hours. After the reaction was completed, n-hexane was removed from the reaction solution by rotary evaporation. Then the reaction solution was cooled again to a temperature of 30° C., and boron tribromide solution (21 mmol) was added. Raise the temperature to room temperature, and the reaction solution was stirred for 0.5 hour. Subsequently, the reaction solution was cooled to a temperature of 0° C., and N,N-diisopropylethylamine (42 mmol) was added dropwise. After the dropping was completed, raise the temperature to room temperature under a stirring state. Continue to raise the temperature to 120° C., the reaction solution was stirred for 3 hours, and then cooled to room temperature. Sodium carbonate aqueous solution and ethyl acetate were added into the reaction solution to quench the reaction. The aqueous phase was extracted with ethyl acetate and the organic phases were merged, and the solvent was removed by rotary evaporation to obtain a crude product. Then the crude product was purified by column chromatography to obtain a pure product. Finally, the pure product was further purified by recrystallization using toluene and ethyl acetate as solvents, to obtain a light yellow solid powder that was the compound 2 with yield of 38.4%. MS=869.

### Example 3

Synthetic Route of Compound 3 is as follows:

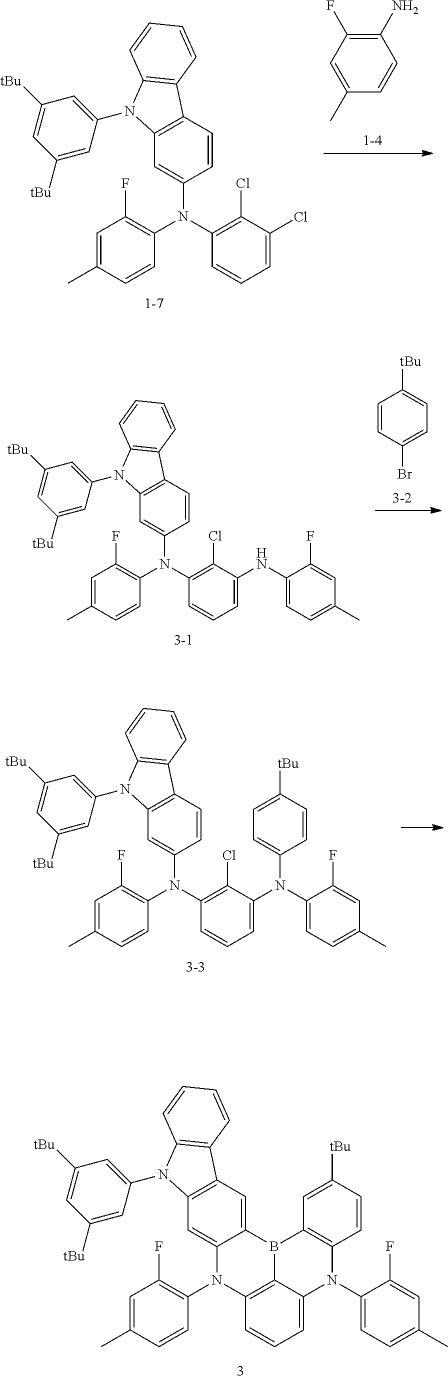

Synthetic Steps of Compound 3 are as follows:

### 1) Synthesis of Intermediate 3-1

Compound 1-7 (10 mmol), compound 1-4 (10 mmol), Pd(dba)₂ (0.1 mmol), TTBP (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 3-1 (6.39 mmol) with yield of 63.9%. MS (ASAP)=711.

### 2) Synthesis of Intermediate 3-3

Compound 3-1 (10 mmol), compound 3-2 (10 mmol), Pd(dba)₂ (0.1 mmol), TTBP (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 3-3 (5.47 mmol) with yield of 54.7%. MS (ASAP)=843.

### 3) Synthesis of Compound 3

The intermediate 3-3 (10 mmol) and dried tert-butyl benzene (100 mL) were added into a three necked-flask (250 mL), and cooled to a temperature of 30° C. in a nitrogen atmosphere. n-hexane solution containing tert-butyllithium (t-BuLi, 21 mmol) was added into the solution dropwise. Raise the temperature of the solution to 60° C., then the solution was reacted for 2 hours. After the reaction was completed, n-hexane was removed from the reaction solution by rotary evaporation. Then the reaction solution was cooled again to a temperature of 30° C., and boron tribromide solution (21 mmol) was added. Raise the temperature to room temperature, and the reaction solution was stirred for 0.5 hour. Subsequently, the reaction solution was cooled to a temperature of 0° C., and N,N-diisopropylethylamine (42 mmol) was added dropwise. After the dropping was completed, raise the temperature to room temperature under a stirring state. Continue to raise the temperature to 120° C., the reaction solution was stirred for 3 hours, and then cooled to room temperature. Sodium carbonate aqueous solution and ethyl acetate were added into the reaction solution to quench the reaction. The aqueous phase was extracted with ethyl acetate and the organic phases were merged, and the solvent was removed by rotary evaporation to obtain a crude product. Then the crude product was purified by column chromatography to obtain a pure product. Finally, the pure product was further purified by recrystallization using toluene and ethyl acetate as solvents, to obtain a light yellow solid powder that was the compound 3 with yield of 29.4%. MS-817.

### Example 4

Synthetic Route of Compound 4 is as follows:

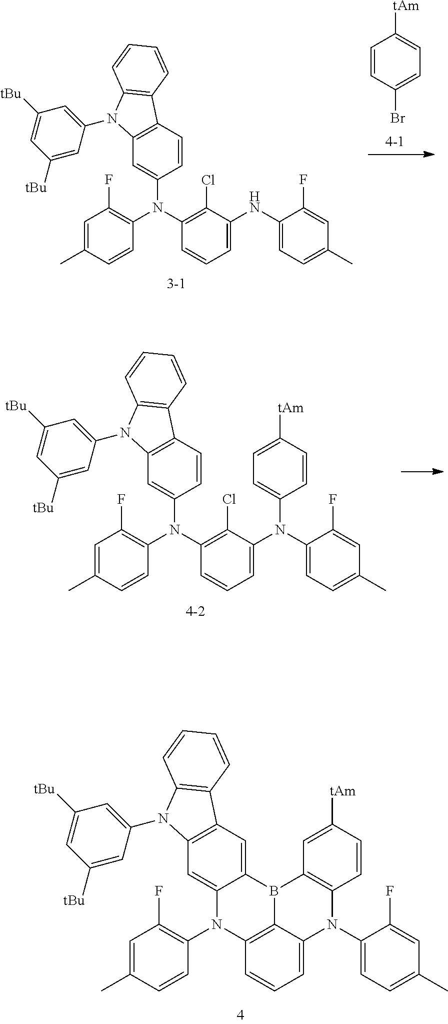

Synthetic Steps of Compound 4 are as follows:

### 1) Synthesis of Intermediate 4-2

Compound 3-1 (10 mmol), compound 4-1 (10 mmol), Pd(dba)₂ (0.1 mmol), TTBP (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 4-2 (5.15 mmol) with yield of 51.5%. MS (ASAP)=857.

### 2) Synthesis of Compound 4

The intermediate 4-2 (10 mmol) and dried tert-butyl benzene (100 mL) were added into a three necked-flask (250 mL), and cooled to a temperature of 30° C. in a nitrogen atmosphere. n-hexane solution containing tert-butyllithium (t-BuLi, 21 mmol) was added into the solution dropwise. Raise the temperature of the solution to 60° C., then the solution was reacted for 2 hours. After the reaction was completed, n-hexane was removed from the reaction solution by rotary evaporation. Then the reaction solution was cooled again to a temperature of 30° C., and boron tribromide solution (21 mmol) was added. Raise the temperature to room temperature, and the reaction solution was stirred for 0.5 hour. Subsequently, the reaction solution was cooled to a temperature of 0° C., and N,N-diisopropylethylamine (42 mmol) was added dropwise. After the dropping was completed, raise the temperature to room temperature under a stirring state. Continue to raise the temperature to 120° C., the reaction solution was stirred for 3 hours, and then cooled to room temperature. Sodium carbonate aqueous solution and ethyl acetate were added into the reaction solution to quench the reaction. The aqueous phase was extracted with ethyl acetate and the organic phases were merged, and the solvent was removed by rotary evaporation to obtain a crude product. Then the crude product was purified by column chromatography to obtain a pure product. Finally, the pure product was further purified by recrystallization using toluene and ethyl acetate as solvents, to obtain a light yellow solid powder that was the compound 4 with yield of 33.5%. MS=831.

### Example 5

Synthetic Route of Compound 5 is as follows:

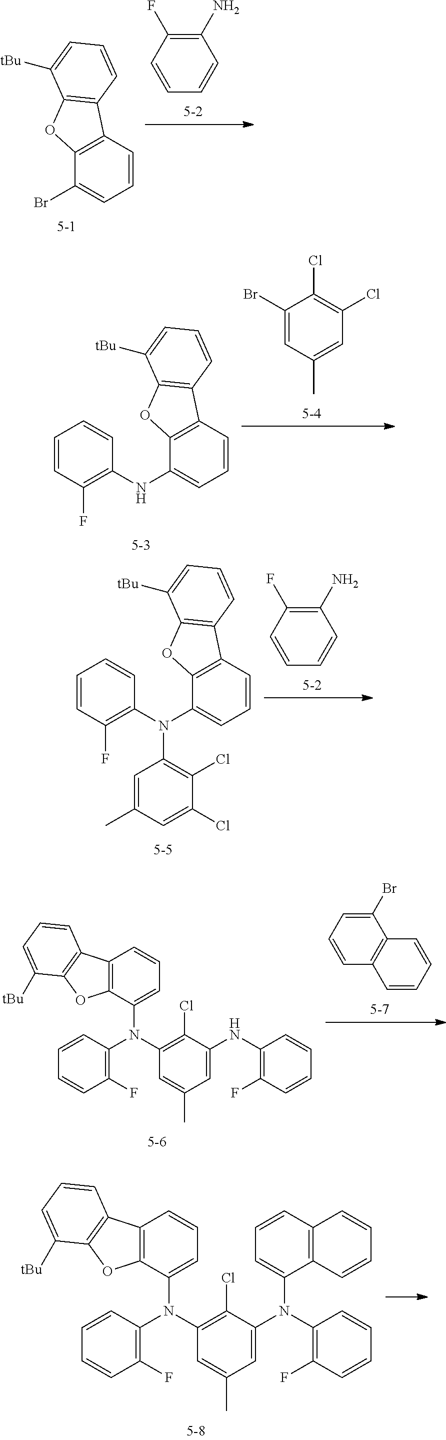

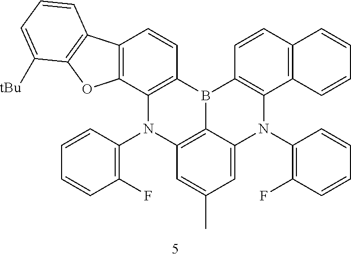 [SMILES: Cc1cc2c3c(c1)N(c1ccccc1F)c1c(ccc4c1oc1c(C(C)(C)C)cccc14)B3c1ccc3ccccc3c1N2c1ccccc1F]

Synthetic Steps of Compound 5 are as follows:

### 1) Synthesis of Intermediate 5-3

Compound 5-1 (10 mmol), compound 5-2 (10 mmol), CuI (10 mmol), and tripotassium phosphate (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 5-3 (8.74 mmol) with yield of 87.4%. MS (ASAP)=333.

### 2) Synthesis of Intermediate 5-5

Compound 5-3 (10 mmol), compound 5-4 (10 mmol), Pd-132 (0.1 mmol), SPhos (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 5-5 (6.67 mmol) with yield of 66.7%. MS (ASAP)=477.

### 3) Synthesis of Intermediate 5-6

Compound 5-5 (10 mmol), compound 5-2 (10 mmol), Pd(dba)₂ (0.1 mmol), TTBP (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 5-6 (5.97 mmol) with yield of 59.7%. MS (ASAP)=566.

### 4) Synthesis of Intermediate 5-8

Compound 5-6 (10 mmol), compound 5-7 (10 mmol), Pd(dba)₂ (0.1 mmol), TTBP (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 5-8 (4.97 mmol) with yield of 49.7%. MS (ASAP)=692.

### 5) Synthesis of Compound 5

The intermediate 5-8 (10 mmol) and dried tert-butyl benzene (100 mL) were added into a three necked-flask (250 mL), and cooled to a temperature of 30° C. in a nitrogen atmosphere. n-hexane solution containing tert-butyllithium (t-BuLi, 21 mmol) was added into the solution dropwise. Raise the temperature of the solution to 60° C., then the solution was reacted for 2 hours. After the reaction was completed, n-hexane was removed from the reaction solution by rotary evaporation. Then the reaction solution was cooled again to a temperature of 30° C., and boron tribromide solution (21 mmol) was added. Raise the temperature to room temperature, and the reaction solution was stirred for 0.5 hour. Subsequently, the reaction solution was cooled to a temperature of 0° C., and N,N-diisopropylethylamine (42 mmol) was added dropwise. After the dropping was completed, raise the temperature to room temperature under a stirring state. Continue to raise the temperature to 120° C., the reaction solution was stirred for 3 hours, and then cooled to room temperature. Sodium carbonate aqueous solution and ethyl acetate were added into the reaction solution to quench the reaction. The aqueous phase was extracted with ethyl acetate and the organic phases were merged, and the solvent was removed by rotary evaporation to obtain a crude product. Then the crude product was purified by column chromatography to obtain a pure product. Finally, the pure product was further purified by recrystallization using toluene and ethyl acetate as solvents, to obtain a light yellow solid powder that was the compound 5 with yield of 41.4%. MS=666.

### Example 6

Synthetic Route of Compound 6 is as follows:

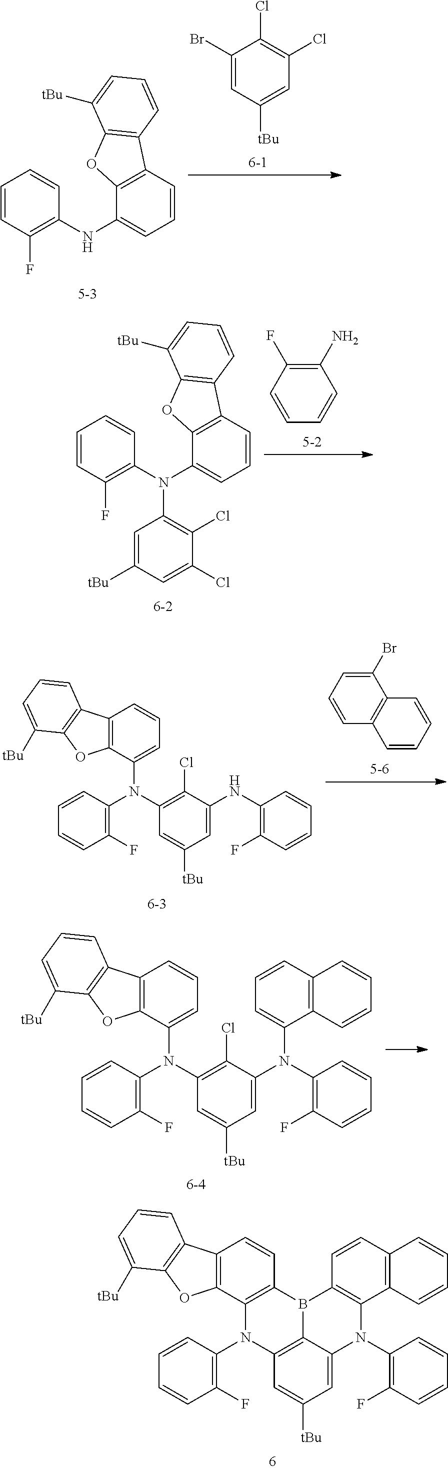

Synthetic Steps of Compound 6 are as follows:

### 1) Synthesis of Intermediate 6-2

Compound 5-3 (10 mmol), compound 6-1 (10 mmol), Pd-132 (0.1 mmol), SPhos (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 6-2 (6.25 mmol) with yield of 62.5%. MS (ASAP)=533.

### 2) Synthesis of Intermediate 6-3

Compound 6-2 (10 mmol), compound 5-2 (10 mmol), Pd(dba)₂ (0.1 mmol), TTBP (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 6-3 (5.11 mmol) with yield of 51.1%. MS (ASAP)=608.

### 3) Synthesis of Intermediate 6-4

Compound 6-3 (10 mmol), compound 5-6 (10 mmol), Pd(dba)₂ (0.1 mmol), TTBP (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 6-4 (5.09 mmol) with yield of 50.9%. MS (ASAP)=734.

### 4) Synthesis of Compound 6

The intermediate 6-4 (10 mmol) and dried tert-butyl benzene (100 mL) were added into a three necked-flask (250 mL), and cooled to a temperature of 30° C. in a nitrogen atmosphere. n-hexane solution containing tert-butyllithium (t-BuLi, 21 mmol) was added into the solution dropwise. Raise the temperature of the solution to 60° C. then the solution was reacted for 2 hours. After the reaction was completed, n-hexane was removed from the reaction solution by rotary evaporation. Then the reaction solution was cooled again to a temperature of 30° C., and boron tribromide solution (21 mmol) was added. Raise the temperature to room temperature, and the reaction solution was stirred for 0.5 hour. Subsequently, the reaction solution was cooled to a temperature of 0° C., and N,N-diisopropylethylamine (42 mmol) was added dropwise. After the dropping was completed, raise the temperature to room temperature under a stirring state. Continue to raise the temperature to 120° C., the reaction solution was stirred for 3 hours, and then cooled to room temperature. Sodium carbonate aqueous solution and ethyl acetate were added into the reaction solution to quench the reaction. The aqueous phase was extracted with ethyl acetate and the organic phases were merged, and the solvent was removed by rotary evaporation to obtain a crude product. Then the crude product was purified by column chromatography to obtain a pure product. Finally, the pure product was further purified by recrystallization using toluene and ethyl acetate as solvents, to obtain a light yellow solid powder that was the compound 6 with yield of 29.6%. MS=708.

### Example 7

Synthetic Route of Compound 7 is as follows:

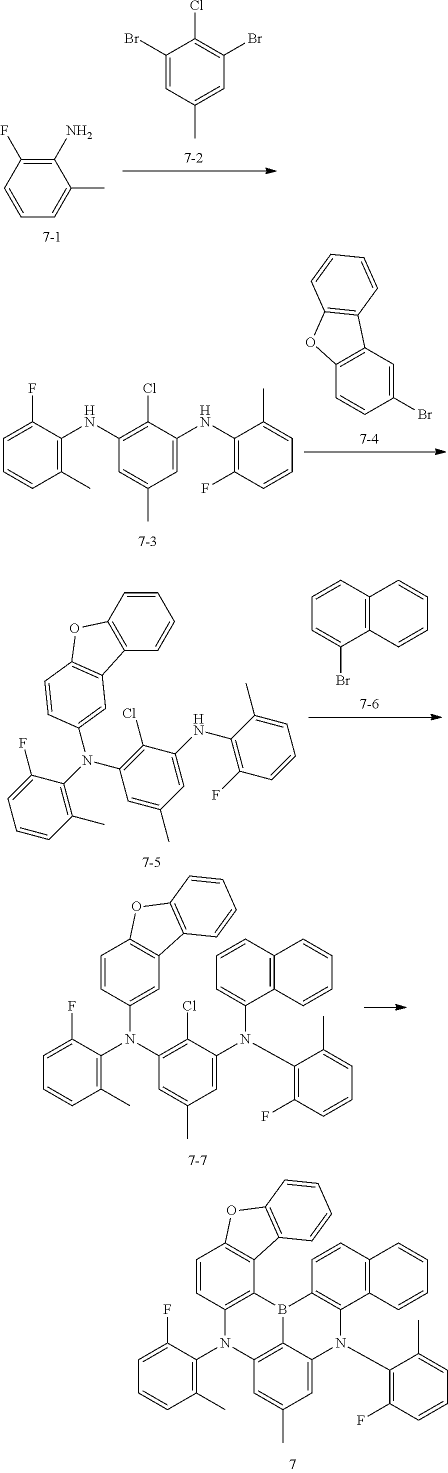

Synthetic Steps of Compound 7 are as follows:

### 1) Synthesis of Intermediate 7-3

Compound 7-1 (10 mmol), compound 7-2 (10 mmol), CuI (10 mmol), and tripotassium phosphate (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 7-3 (8.53 mmol) with yield of 85.3%. MS (ASAP)=372.

### 2) Synthesis of Intermediate 7-5

Compound 7-3 (10 mmol), compound 7-4 (10 mmol), Pd-132 (0.1 mmol), SPhos (0.2 mmol), and sodium tert-butoxide (30 mmol) were dissolved in toluene, and stirred for 6 hours at a temperature of 100°° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 7-5 (6.34 mmol) with yield of 63.4%. MS (ASAP)=538.

### 3) Synthesis of Intermediate 7-7

Compound 7-5 (10 mmol), compound 7-6 (10 mmol), Pd(dba)₂ (0.1 mmol), TTBP (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 7-7 (5.36 mmol) with yield of 53.6%. MS (ASAP)=664.

### 4) Synthesis of Compound 7

The intermediate 7-7 (10 mmol) and dried tert-butyl benzene (100 mL) were added into a three necked-flask (250 mL), and cooled to a temperature of 30° C. in a nitrogen atmosphere. n-hexane solution containing tert-butyllithium (t-BuLi, 21 mmol) was added into the solution dropwise. Raise the temperature of the solution to 60°° C., then the solution was reacted for 2 hours. After the reaction was completed, n-hexane was removed from the reaction solution by rotary evaporation. Then the reaction solution was cooled again to a temperature of 30° C., and boron tribromide solution (21 mmol) was added. Raise the temperature to room temperature, and the reaction solution was stirred for 0.5 hour. Subsequently, the reaction solution was cooled to a temperature of 0° C., and N,N-diisopropylethylamine (42 mmol) was added dropwise. After the dropping was completed, raise the temperature to room temperature under a stirring state. Continue to raise the temperature to 120° C., the reaction solution was stirred for 3 hours, and then cooled to room temperature. Sodium carbonate aqueous solution and ethyl acetate were added into the reaction solution to quench the reaction. The aqueous phase was extracted with ethyl acetate and the organic phases were merged, and the solvent was removed by rotary evaporation to obtain a crude product. Then the crude product was purified by column chromatography to obtain a pure product. Finally, the pure product was further purified by recrystallization using toluene and ethyl acetate as solvents, to obtain a light yellow solid powder that was the compound 7 with yield of 28.7%. MS=638.

### Example 8

Synthetic Route of Compound 8 is as follows:

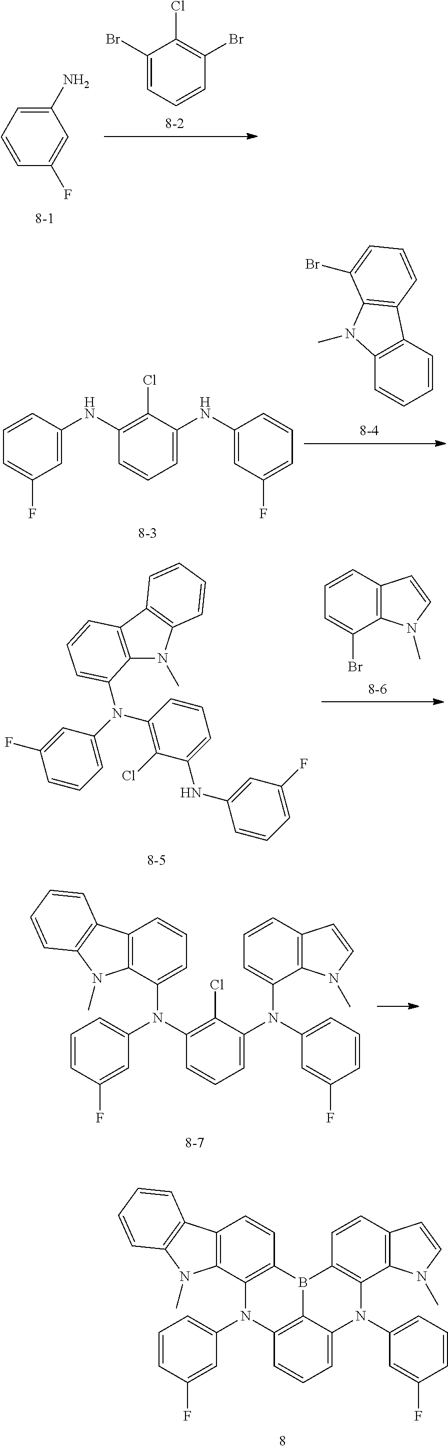

Synthetic Steps of Compound 8 are as follows:

### 1) Synthesis of Intermediate 8-3

Compound 8-1 (10 mmol), compound 8-2 (10 mmol), CuI (10 mmol), and tripotassium phosphate (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 8-3 (8.15 mmol) with yield of 81.5%. MS (ASAP)=330.

### 2) Synthesis of Intermediate 8-5

Compound 8-3 (10 mmol), compound 8-4 (10 mmol), Pd-132 (0.1 mmol), SPhos (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 8-5 (7.45 mmol) with yield of 74.5%. MS (ASAP)=509.

### 3) Synthesis of Intermediate 8-7

Compound 8-5 (10 mmol), compound 8-6 (10 mmol), Pd(dba)₂ (0.1 mmol), TTBP (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 8-7 (5.25 mmol) with yield of 52.5%. MS (ASAP)=638.

### 4) Synthesis of Compound 8

The intermediate 8-7 (10 mmol) and dried tert-butyl benzene (100 mL) were added into a three necked-flask (250 mL), and cooled to a temperature of 30° C. in a nitrogen atmosphere. n-hexane solution containing tert-butyllithium (t-BuLi, 21 mmol) was added into the solution dropwise. Raise the temperature of the solution to 60° C., then the solution was reacted for 2 hours. After the reaction was completed, n-hexane was removed from the reaction solution by rotary evaporation. Then the reaction solution was cooled again to a temperature of 30° C., and boron tribromide solution (21 mmol) was added. Raise the temperature to room temperature, and the reaction solution was stirred for 0.5 hour. Subsequently, the reaction solution was cooled to a temperature of 0° C., and N,N-diisopropylethylamine (42 mmol) was added dropwise. After the dropping was completed, raise the temperature to room temperature under a stirring state. Continue to raise the temperature to 120° C., the reaction solution was stirred for 3 hours, and then cooled to room temperature. Sodium carbonate aqueous solution and ethyl acetate were added into the reaction solution to quench the reaction. The aqueous phase was extracted with ethyl acetate and the organic phases were merged, and the solvent was removed by rotary evaporation to obtain a crude product. Then the crude product was purified by column chromatography to obtain a pure product. Finally, the pure product was further purified by recrystallization using toluene and ethyl acetate as solvents, to obtain a light yellow solid powder that was the compound 8 with yield of 42.3%. MS=612.

### Example 9

Synthetic Route of Compound 9 is as follows:

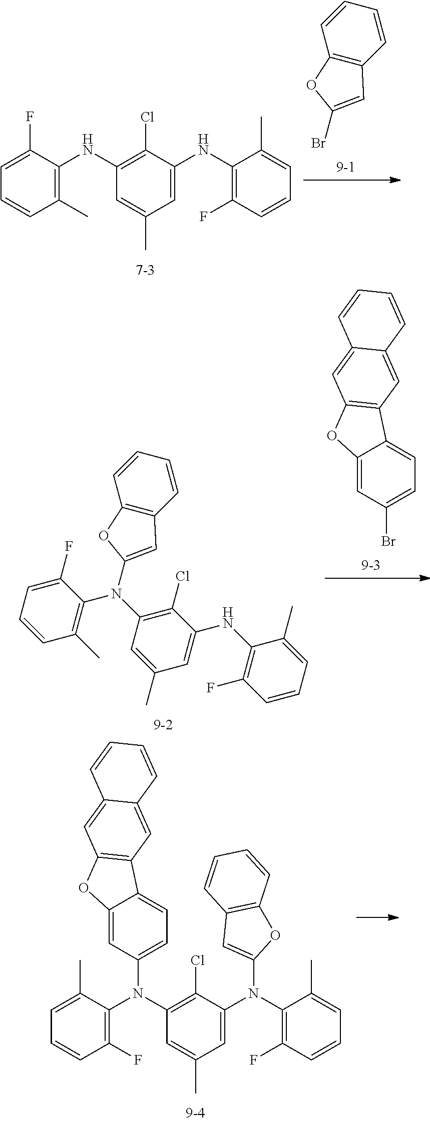

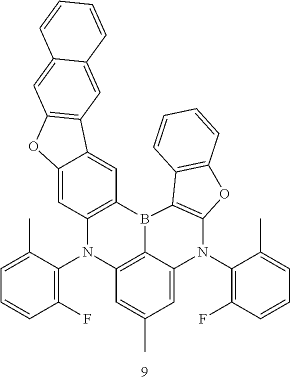 [SMILES: Cc1cc2c3c(c1)N(c1c(C)cccc1F)c1oc4ccccc4c1B3c1cc3c(cc1N2c1c(C)cccc1F)oc1cc2ccccc2cc13]

Synthetic Steps of Compound 9 are as follows:

### 1) Synthesis of Intermediate 9-2

Compound 7-3 (10 mmol), compound 9-1 (10 mmol), Pd-132 (0.1 mmol), SPhos (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 9-2 (6.17 mmol) with yield of 61.7%. MS (ASAP)=488.

### 2) Synthesis of Intermediate 9-4

Compound 9-2 (10 mmol), compound 9-3 (10 mmol), Pd(dba)₂ (0.1 mmol). TTBP (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 9-4 (5.57 mmol) with yield of 55.7%. MS (ASAP)=704.

### 3) Synthesis of Compound 9

The intermediate 9-4 (10 mmol) and dried tert-butyl benzene (100 mL) were added into a three necked-flask (250 mL), and cooled to a temperature of 30° C. in a nitrogen atmosphere. n-hexane solution containing tert-butyllithium (t-BuLi, 21 mmol) was added into the solution dropwise. Raise the temperature of the solution to 60° C., then the solution was reacted for 2 hours. After the reaction was completed, n-hexane was removed from the reaction solution by rotary evaporation. Then the reaction solution was cooled again to a temperature of 30° C., and boron tribromide solution (21 mmol) was added. Raise the temperature to room temperature, and the reaction solution was stirred for 0.5 hour. Subsequently, the reaction solution was cooled to a temperature of 0° C., and N,N-diisopropylethylamine (42 mmol) was added dropwise. After the dropping was completed, raise the temperature to room temperature under a stirring state. Continue to raise the temperature to 120° C., the reaction solution was stirred for 3 hours, and then cooled to room temperature. Sodium carbonate aqueous solution and ethyl acetate were added into the reaction solution to quench the reaction. The aqueous phase was extracted with ethyl acetate and the organic phases were merged, and the solvent was removed by rotary evaporation to obtain a crude product. Then the crude product was purified by column chromatography to obtain a pure product. Finally, the pure product was further purified by recrystallization using toluene and ethyl acetate as solvents, to obtain a light yellow solid powder that was the compound 9 with yield of 36.8%. MS=678.

### Example 10

Synthetic Route of Compound 10 is as follows:

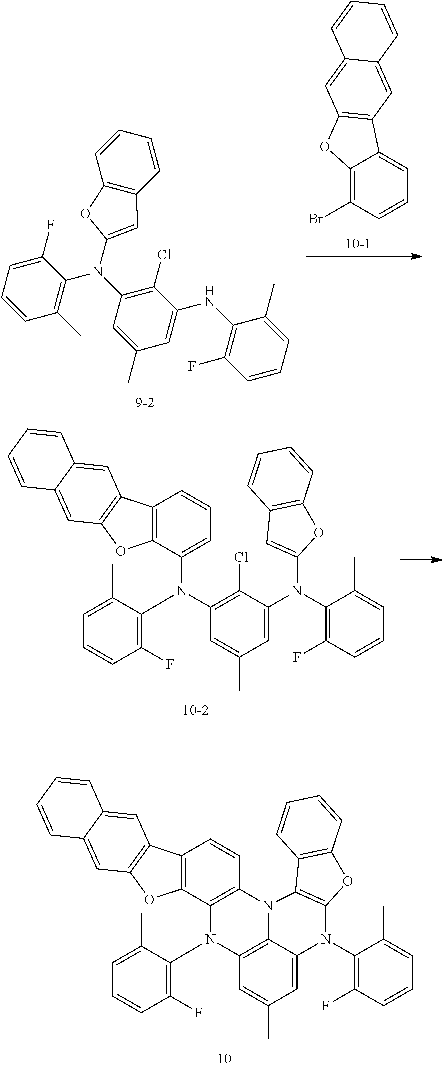 [SMILES: Cc1cc(Nc2c(C)cccc2F)c(Cl)c(N(c2cc3ccccc3o2)c2c(C)cccc2F)c1 ; Brc1cccc2c1oc1cc3ccccc3cc12 ; Cc1cc(N(c2cc3ccccc3o2)c2c(C)cccc2F)c(Cl)c(N(c2c(C)cccc2F)c2cccc3c2oc2cc4ccccc4cc23)c1 ; Cc1cc2c3c(c1)N(c1c(C)cccc1F)c1c(ccc4c1oc1cc5ccccc5cc14)N3c1c(oc3ccccc13)N2c1c(C)cccc1F]

Synthetic Steps of Compound 10 are as follows:

### 1) Synthesis of Intermediate 10-2

Compound 9-2 (10 mmol), compound 10-1 (10 mmol), Pd(dba)₂ (0.1 mmol), TTBP (0.2 mmol), and sodium tert-butoxide (30 mmol) were dissolved in toluene, and stirred for 6 hours at a temperature of 100°° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 10-2 (5.78 mmol) with yield of 57.8%. MS (ASAP)=704.

### 2) Synthesis of Compound 10

The intermediate 10-2 (10 mmol) and dried tert-butyl benzene (100 mL) were added into a three necked-flask (250 mL), and cooled to a temperature of 30° C. in a nitrogen atmosphere. n-hexane solution containing tert-butyllithium (t-BuLi, 21 mmol) was added into the solution dropwise. Raise the temperature of the solution to 60° C., then the solution was reacted for 2 hours. After the reaction was completed, n-hexane was removed from the reaction solution by rotary evaporation. Then the reaction solution was cooled again to a temperature of 30° C., and boron tribromide solution (21 mmol) was added. Raise the temperature to room temperature, and the reaction solution was stirred for 0.5 hour. Subsequently, the reaction solution was cooled to a temperature of 0° C., and N,N-diisopropylethylamine (42 mmol) was added dropwise. After the dropping was completed, raise the temperature to room temperature under a stirring state. Continue to raise the temperature to 120° C., the reaction solution was stirred for 3 hours, and then cooled to room temperature. Sodium carbonate aqueous solution and ethyl acetate were added into the reaction solution to quench the reaction. The aqueous phase was extracted with ethyl acetate and the organic phases were merged, and the solvent was removed by rotary evaporation to obtain a crude product. Then the crude product was purified by column chromatography to obtain a pure product. Finally, the pure product was further purified by recrystallization using toluene and ethyl acetate as solvents, to obtain a light yellow solid powder that was the compound 10 with yield of 39.3%. MS=678.

### Example 11

Synthetic Route of Compound 11 is as follows:

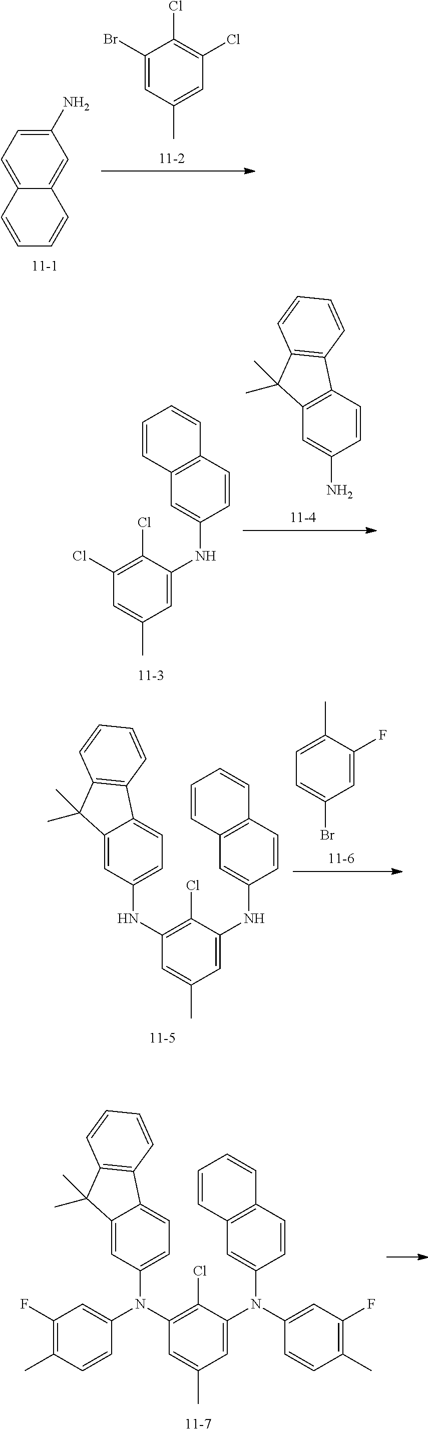

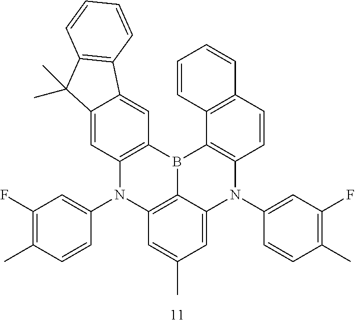 [SMILES: Cc1cc2c3c(c1)N(c1ccc(C)c(F)c1)c1ccc4ccccc4c1B3c1cc3c(cc1N2c1ccc(C)c(F)c1)C(C)(C)c1ccccc1-3]

Synthetic Steps of Compound 11 are as follows:

### 1) Synthesis of Intermediate 11-3

Compound 11-1 (10 mmol), compound 11-2 (10 mmol), CuI (10 mmol), and tripotassium phosphate (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 11-3 (8.24 mmol) with yield of 82.4%. MS (ASAP)=301.

### 2) Synthesis of Intermediate 11-5

Compound 11-3 (10 mmol), compound 11-4 (10 mmol), Pd-132 (0.1 mmol), SPhos (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 11-5 (6.57 mmol) with yield of 65.7%. MS (ASAP)=474.

### 3) Synthesis of Intermediate 11-7

Compound 11-5 (10 mmol), compound 11-6 (10 mmol), Pd(dba)₂ (0.1 mmol), TTBP (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 11-7 (6.84 mmol) with yield of 68.4%. MS (ASAP)=690.

### 4) Synthesis of Compound 11

The intermediate 11-7 (10 mmol) and dried tert-butyl benzene (100 mL) were added into a three necked-flask (250 mL), and cooled to a temperature of 30° C. in a nitrogen atmosphere. n-hexane solution containing tert-butyllithium (t-BuLi, 21 mmol) was added into the solution dropwise. Raise the temperature of the solution to 60° C., then the solution was reacted for 2 hours. After the reaction was completed, n-hexane was removed from the reaction solution by rotary evaporation. Then the reaction solution was cooled again to a temperature of 30° C., and boron tribromide solution (21 mmol) was added. Raise the temperature to room temperature, and the reaction solution was stirred for 0.5 hour. Subsequently, the reaction solution was cooled to a temperature of 0° C., and N,N-diisopropylethylamine (42 mmol) was added dropwise. After the dropping was completed, raise the temperature to room temperature under a stirring state. Continue to raise the temperature to 120° C., the reaction solution was stirred for 3 hours, and then cooled to room temperature. Sodium carbonate aqueous solution and ethyl acetate were added into the reaction solution to quench the reaction. The aqueous phase was extracted with ethyl acetate and the organic phases were merged, and the solvent was removed by rotary evaporation to obtain a crude product. Then the crude product was purified by column chromatography to obtain a pure product. Finally, the pure product was further purified by recrystallization using toluene and ethyl acetate as solvents, to obtain a light yellow solid powder that was the compound 11 with yield of 36.9%. MS=664.

### Example 12

Synthetic Route of Compound 12 is as follows:

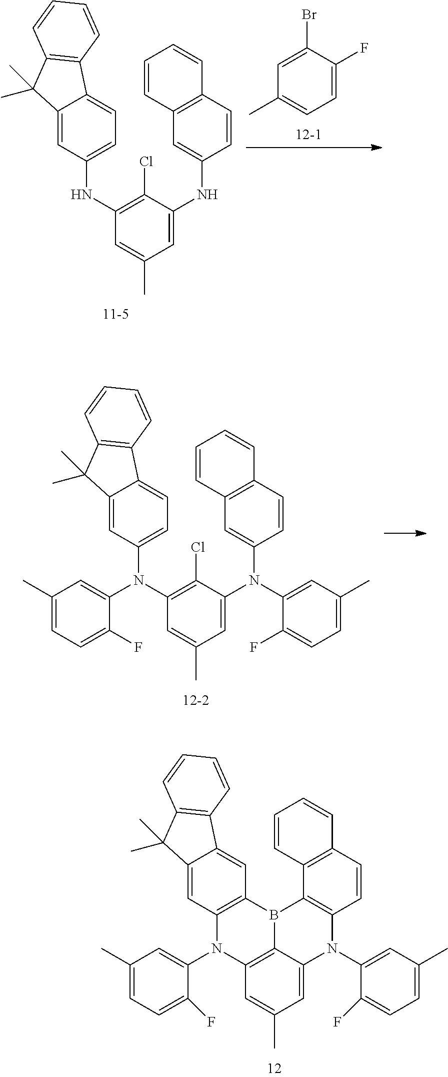

Synthetic Steps of Compound 12 are as follows:

### 1) Synthesis of Intermediate 12-2

Compound 11-5 (10 mmol), compound 12-1 (10 mmol), Pd(dba)₂ (0.1 mmol), TTBP (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 12-2 (6.27 mmol) with yield of 62.7%. MS (ASAP)=690.

### 2) Synthesis of Compound 12

The intermediate 12-2 (10 mmol) and dried tert-butyl benzene (100 mL) were added into a three necked-flask (250 mL), and cooled to a temperature of 30° C. in a nitrogen atmosphere. n-hexane solution containing tert-butyllithium (t-BuLi, 21 mmol) was added into the solution dropwise. Raise the temperature of the solution to 60° C., then the solution was reacted for 2 hours. After the reaction was completed, n-hexane was removed from the reaction solution by rotary evaporation. Then the reaction solution was cooled again to a temperature of 30° C., and boron tribromide solution (21 mmol) was added. Raise the temperature to room temperature, and the reaction solution was stirred for 0.5 hour. Subsequently, the reaction solution was cooled to a temperature of 0° C., and N,N-diisopropylethylamine (42 mmol) was added dropwise. After the dropping was completed, raise the temperature to room temperature under a stirring state. Continue to raise the temperature to 120° C., the reaction solution was stirred for 3 hours, and then cooled to room temperature. Sodium carbonate aqueous solution and ethyl acetate were added into the reaction solution to quench the reaction. The aqueous phase was extracted with ethyl acetate and the organic phases were merged, and the solvent was removed by rotary evaporation to obtain a crude product. Then the crude product was purified by column chromatography to obtain a pure product. Finally, the pure product was further purified by recrystallization using toluene and ethyl acetate as solvents, to obtain a light yellow solid powder that was the compound 12 with yield of 45.7%. MS=664.

### Example 13

Synthetic Route of Compound 13 is as follows

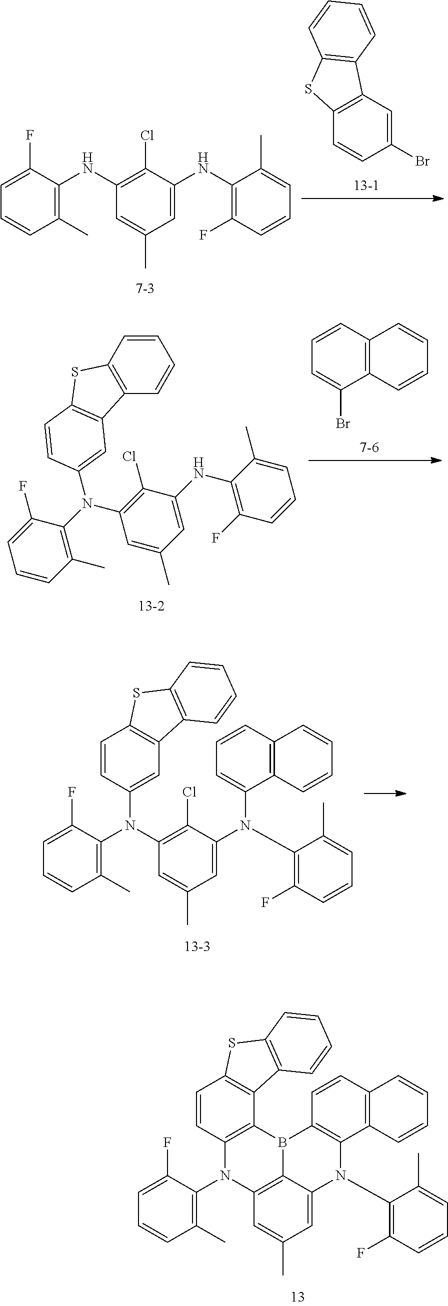 [SMILES: Cc1cc(Nc2c(C)cccc2F)c(Cl)c(Nc2c(C)cccc2F)c1 ; Brc1ccc2sc3ccccc3c2c1 ; Cc1cc(Nc2c(C)cccc2F)c(Cl)c(N(c2ccc3sc4ccccc4c3c2)c2c(C)cccc2F)c1 ; Brc1cccc2ccccc12 ; Cc1cc(N(c2ccc3sc4ccccc4c3c2)c2c(C)cccc2F)c(Cl)c(N(c2c(C)cccc2F)c2cccc3ccccc23)c1 ; Cc1cc2c3c(c1)N(c1c(C)cccc1F)c1c(ccc4ccccc14)B3c1c(ccc3sc4ccccc4c13)N2c1c(C)cccc1F]

Synthetic Steps of Compound 13 are as follows:

### 1) Synthesis of Intermediate 13-2

Compound 7-3 (10 mmol), compound 13-1 (10 mmol), Pd-132 (0.1 mmol), SPhos (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 13-2 (6.17 mmol) with yield of 61.7%. MS (ASAP)=554.

### 2) Synthesis of Intermediate 13-3

Compound 13-2 (10 mmol), compound 7-6 (10 mmol), Pd(dba)₂ (0.1 mmol), TTBP (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water, and then purified by column chromatography to obtain the intermediate 13-3 (5.94 mmol) with yield of 59.4%. MS (ASAP)=680.

### 3) Synthesis of Compound 13

The intermediate 13-3 (10 mmol) and dried tert-butyl benzene (100 mL) were added into a three necked-flask (250 mL), and cooled to a temperature of 30° C. in a nitrogen atmosphere. n-hexane solution containing tert-butyllithium (t-BuLi, 21 mmol) was added into the solution dropwise. Raise the temperature of the solution to 60° C., then the solution was reacted for 2 hours. After the reaction was completed, n-hexane was removed from the reaction solution by rotary evaporation. Then the reaction solution was cooled again to a temperature of 30° C., and boron tribromide solution (21 mmol) was added. Raise the temperature to room temperature, and the reaction solution was stirred for 0.5 hour. Subsequently, the reaction solution was cooled to a temperature of 0° C., and N,N-diisopropylethylamine (42 mmol) was added dropwise. After the dropping was completed, raise the temperature to room temperature under a stirring state. Continue to raise the temperature to 120° C., the reaction solution was stirred for 3 hours, and then cooled to room temperature. Sodium carbonate aqueous solution and ethyl acetate were added into the reaction solution to quench the reaction. The aqueous phase was extracted with ethyl acetate and the organic phases were merged, and the solvent was removed by rotary evaporation to obtain a crude product. Then the crude product was purified by column chromatography to obtain a pure product. Finally, the pure product was further purified by recrystallization using toluene and ethyl acetate as solvents, to obtain a light yellow solid powder that was the compound 13 with yield of 33.5%. MS=654.

### Comparative Example 1

Comparative compound 1 provided in the comparative example 1 has the following structure:

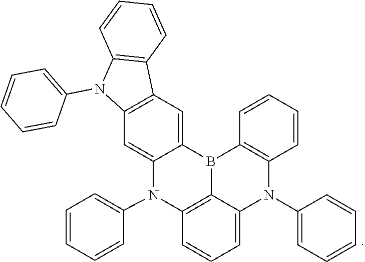 [SMILES: c1ccc(N2c3ccccc3B3c4cc5c6ccccc6n(-c6ccccc6)c5cc4N(c4ccccc4)c4cccc2c43)cc1]

Energy levels of the compounds 1-13 provided in the above-mentioned examples 1-13 and the comparative compound 1 provided in the comparative example 1 were tested according to the following methods.

The energy levels of the compounds 1-13 and the comparative compound 1 can be obtained by quantum calculation, such as Gaussian 09W (Gaussian Inc.) using time-dependent density functional theory (TD-DFT), specific simulation methods can refer to patent application WO2011/41110, which is incorporated herein by reference.

First, a semi empirical method “Ground State/Semi-empirical/Default Spin/AM1” (Charge0/Spin Singlet) was used to optimize molecular geometry, and then energy structures of organic molecules were calculated by the TD-DFT method to obtain “TD-SCF/DFT/Default Spin/B3PW91” and the base group “6-31G (d)” (Charge0/Spin Singlet). HOMO and LUMO energy levels were calculated according to the following calibration equations, and energy levels of singlet state (S1), triplet state (T1), and resonance factor f (S1) were used directly:

$$H O M O ( eV ) = ( H O M O ( G ) \times 27.212 ) - 0.9 \; 899 ) / 1.1206 ; L U M O ( eV ) = ( L U M O ( G ) \times 27.212 ) - 2.0 \; 041 ) / 1.385 .$$

In the equations above, energy levels of HOMO, LUMO, T1, and S1 were the calculation results of Gaussian 09W, in Hartree, and the results were shown in the following table 1, in which ΔEst indicates the difference between T1 and S1.

TABLE 1

| | HOMO | LUMO | T1 | S1 | ΔEst |
|---|---|---|---|---|---|
| Compound | (eV) | (eV) | (eV) | (eV) | (eV) |
| Compound 1 | −5.14 | −2.26 | 2.51 | 3.04 | 0.53 |
| Compound 2 | −5.21 | −2.29 | 2.56 | 3.03 | 0.47 |
| Compound 3 | −5.08 | −2.31 | 2.5 | 2.99 | 0.49 |
| Compound 4 | −5.16 | −2.28 | 2.59 | 3.04 | 0.45 |
| Compound 5 | −5.12 | −2.29 | 2.53 | 3.01 | 0.48 |
| Compound 6 | −5.13 | −2.31 | 2.49 | 2.99 | 0.50 |
| Compound 7 | −5.04 | −2.26 | 2.55 | 3.05 | 0.50 |
| Compound 8 | −5.09 | −2.27 | 2.61 | 3.03 | 0.42 |
| Compound 9 | −5.13 | −2.24 | 2.48 | 2.96 | 0.48 |
| Compound 10 | −5.27 | −2.33 | 2.53 | 3.00 | 0.47 |
| Compound 11 | −5.1 | −2.19 | 2.55 | 2.97 | 0.42 |
| Compound 12 | −5.04 | −2.28 | 2.59 | 3.08 | 0.49 |
| Compound 13 | −5.06 | −2.30 | 2.53 | 3.01 | 0.48 |
| Comparative | −5.01 | −2.13 | 2.41 | 2.81 | 0.40 |
| compound 1 | | | | | |

According to the results of the energy levels shown in table 1 above, ΔEst of the compounds 1-13 according to the examples of the present disclosure is greater than the comparative compound 1, mostly around 0.5 eV, indicating that emission colors of the compounds 1-13 are closer to dark blue.

### Preparation and Characterization of Organic Electronic Devices

Organic electronic devices were prepared by using the compounds 1-13 according to the above-mentioned examples, the comparative compound 1 according to the comparative example 1, and compounds BH, ET, and Liq that having the following structures:

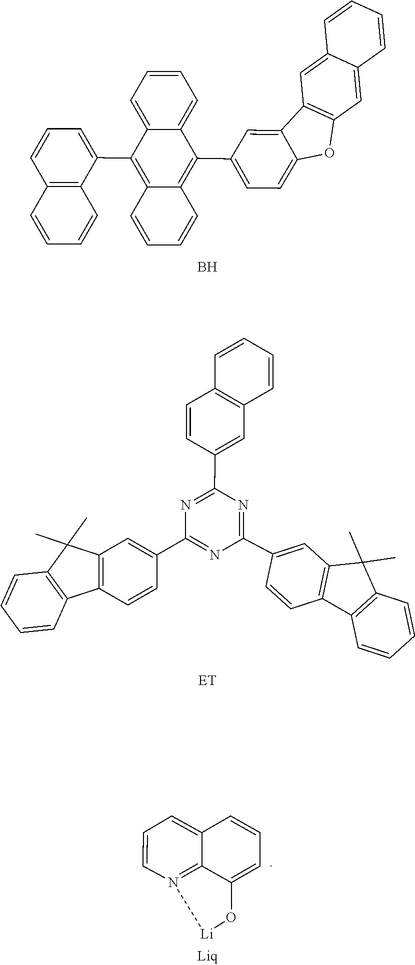

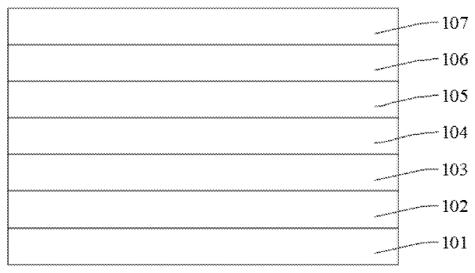

The prepared organic electronic devices are OLED devices, each of the with OLED devices has a structure shown in FIG. 1, including a substrate 101, an anode 102, a hole injection layer 103, a hole transport layer 104, a light-emitting layer 105, an electron transport layer 106, and a cathode 107.

### Preparation of OLED-1

Step a, cleaning of an ITO conductive glass substrate. The ITO conductive glass substrate used as an anode was cleaned using solvent including one or more of chloroform, acetone, and isopropanol, followed by UV ozone treatment.

Step b, preparation of a hole injection layer (HIL). Poly(3,4-ethylenedioxythiophene) (PEDOT, Clevios™ AI4083) was coated on the ITO conductive glass substrate by a spin way in a super clean room, then treated on a hot plate at a temperature of 180° C. for 10 minutes to obtain the HIL with a thickness of 40 nm.

Step c, preparation of a hole transport layer (HTL). Toluene was used as a solvent to obtain a TFB or polyvinylcarbazole (PVK, Sigma Aldrich, an average relative molecular mass ranging from 25000 to 50000) solution, in which the TFB or PVK has a concentration of 5 mg/ml. Then the TFB or PVK solution was coated on the HIL by a spin way in a nitrogen glovebox, and then treated on a hot plate at a temperature of 180° C. for 60 minutes to obtain the HTL with a thickness of 20 nm.

Step d, preparation of a light-emitting layer (EML). A methyl benzoate solution was coated on the HTL by a spin way in a nitrogen glovebox, and then treated on a hot plate at a temperature of 140° C. for 10 minutes to obtain the EML with a thickness of 40 nm. Solvent in the methyl benzoate solution was methyl benzoate, and light-emitting materials in the methyl benzoate solution were a mixture of a host material that is the BH and a guest material that is the above-mentioned compound 1. A weight of the host material to a weight of the guest material was 95:5, and the light-emitting materials have a concentration of 15 mg/ml.

Step e, preparations of an electron transport layer and a cathode. The substrate after the heat treatment was transferred to a vacuum chamber, ET and Liq were placed in different evaporation units, and co-deposited on the EML at a ratio of 50 wt % in high vacuum (1×10⁻⁶ millibars) to obtain the electron transport layer with a thickness of 20 nm. Then Al was deposited on the electron transport layer to obtain the cathode with a thickness of 100 nm.

Step f, encapsulation. The above-mentioned device was encapsulated by UV cured resin to obtain the OLED-1.

### Preparation of OLED-2

The OLED-2 was prepared according to the preparation method of OLED-1, and the only difference from OLED-1 is that the guest material in step d is replaced with the compound 2 mentioned above.

### Preparation of OLED-3

The OLED-3 was prepared according to the preparation method of OLED-1, and the only difference from OLED-1 is that the guest material in step d is replaced with the compound 3 mentioned above.

### Preparation of OLED-4

The OLED-4 was prepared according to the preparation method of OLED-1, and the only difference from OLED-1 is that the guest material in step d is replaced with the compound 4 mentioned above.

### Preparation of OLED-5

The OLED-5 was prepared according to the preparation method of OLED-1, and the only difference from OLED-1 is that the guest material in step d is replaced with the compound 5 mentioned above.

### Preparation of OLED-6

The OLED-6 was prepared according to the preparation method of OLED-1, and the only difference from OLED-1 is that the guest material in step d is replaced with the compound 6 mentioned above.

### Preparation of OLED-7

The OLED-7 was prepared according to the preparation method of OLED-1, and the only difference from OLED-1 is that the guest material in step d is replaced with the compound 7 mentioned above.

### Preparation of OLED-8

The OLED-8 was prepared according to the preparation method of OLED-1, and the only difference from OLED-1 is that the guest material in step d is replaced with the compound 8 mentioned above.

### Preparation of OLED-9

The OLED-9 was prepared according to the preparation method of OLED-1, and the only difference from OLED-1 is that the guest material in step d is replaced with the compound 9 mentioned above.

### Preparation of OLED-10

The OLED-10 was prepared according to the preparation method of OLED-1, and the only difference from OLED-1 is that the guest material in step d is replaced with the compound 10 mentioned above.

### Preparation of OLED-11

The OLED-11 was prepared according to the preparation method of OLED-1, and the only difference from OLED-1 is that the guest material in step d is replaced with the compound 11 mentioned above.

### Preparation of OLED-12

The OLED-12 was prepared according to the preparation method of OLED-1, and the only difference from OLED-1 is that the guest material in step d is replaced with the compound 12 mentioned above.

### Preparation of OLED-13

The OLED-13 was prepared according to the preparation method of OLED-1, and the only difference from OLED-1 is that the guest material in step d is replaced with the compound 13 mentioned above.

### Preparation of OLED-Ref

The OLED-Ref was prepared according to the preparation method of OLED-1, and the only difference from OLED-1 is that the guest material in step d is replaced with the comparative compound 1 mentioned above.

Current-voltage (J-V) characteristic of each OLED device obtained from the above-mentioned preparation was tested, and important parameters including color coordinate (CIE, (X, Y)), voltage@1 knits (V), current efficiency (CE@1 knits), and life (LT90@1 knits) were recorded, and results were shown in table 2.

TABLE 2

| | | Voltage | CE | LT90 @ |
|---|---|---|---|---|
| | CIE | @1 knits | @1 knits | 1 knits |
| OLED device | (X, Y) | (V) | (cd/A) | (h) |
| OLED-1 | 0.141, 0.084 | 5.5 | 6.4 | 170 |
| OLED-2 | 0.141, 0.086 | 5.5 | 6.3 | 161 |
| OLED-3 | 0.141, 0.081 | 5.5 | 6.4 | 165 |
| OLED-4 | 0.141, 0.083 | 5.5 | 6.1 | 167 |
| OLED-5 | 0.143, 0.081 | 5.5 | 5.8 | 142 |
| OLED-6 | 0.143, 0.083 | 5.5 | 5.9 | 140 |
| OLED-7 | 0.142, 0.087 | 5.5 | 5.7 | 145 |
| OLED-8 | 0.141, 0.084 | 5.5 | 5.6 | 139 |
| OLED-9 | 0.143, 0.084 | 5.5 | 5.8 | 140 |
| OLED-10 | 0.142, 0.086 | 5.6 | 5.8 | 141 |
| OLED-11 | 0.141, 0.085 | 5.5 | 5.5 | 138 |
| OLED-12 | 0.143, 0.083 | 5.5 | 5.8 | 141 |
| OLED-13 | 0.143, 0.081 | 5.5 | 5.9 | 148 |
| OLED-Ref | 0.153, 0.127 | 6.2 | 3 | 81 |

It can be seen from table 2 that the CIE of the OLED-1 to OLED-13 is better than the CIE of the OLED-Ref, this is because fluorine atoms are introduced in specific sites of each of the compounds 1-13 according to the examples of the present disclosure, making the emission color closer to dark blue.

In addition, compared to the OLED-Ref, the OLED-1 to OLED-13 have higher current efficiency ranging from 5.5 cd/A to 6.4 cd/A and longer life ranging from 138 hours to 170 hours. Specifically, compared to the OLED-Ref, the life of the OLED-1 to OLED-13 is increased by 80%to 90%.

The current efficiency of the OLED devices prepared by using the compounds 1-4 as guest materials in the light-emitting layers ranges from 6.1 cd/A to 6.4 cd/A, and the life of these OLED devices is greater than 160 hours. That is, the OLED devices prepared by using the compounds 1-4 have excellent current efficiency and life. This is because multiple tert-butyl or tert-amyl, and fluorine atoms are further introduced in the compounds 1-4, compared to the comparative compound 1, making overall molecular solubility of the compounds 1-4 better and purification of these compounds easier, thereby improving purity of these compounds, and further improving luminous efficiency and life of the devices using these compounds. In addition, compared to the comparative compound 1, since tetrahydronaphthalene or indene is introduced in the compounds 5-13, overall molecular conjugation of the compounds 5-13 is increased, thus improving luminous efficiency and life of the devices using these compounds.

Based on the above, the OLED devices prepared by using the organic boron nitride compounds according to the examples of the present disclosure as guest materials in the light-emitting layers have higher current efficiency, longer life, and dark blue emission color.

The organic boron-nitrogen compound, the organic electronic device, and the electronic apparatus provided by the embodiments of the present disclosure are described in detail. In this context, specific embodiments are adopted to illustrate a principle and implementation modes of the present disclosure. The description of the above-mentioned embodiments is only used to help understand methods and a core idea of the present disclosure. At the same time, for those skilled in the art, according to the idea of the present disclosure, there might be changes in specific implementation modes and a scope of the present disclosure, which falls within the scope of the protection of the present disclosure. In conclusion, contents of the specification should not be interpreted as a limitation of the present disclosure.

What is claimed is:

1. An organic boron-nitrogen compound represented by Formula (I): 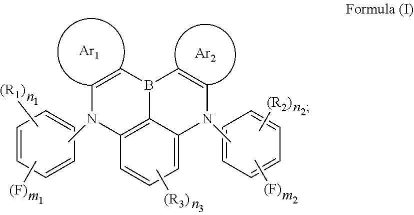
wherein Ar₁ is represented by following formula: 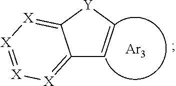
and
Ar₂ is represented by any one of following formulas: 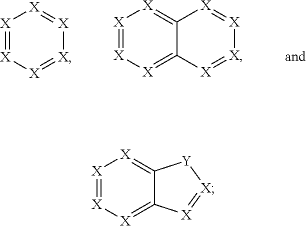
wherein X is independently selected from CR₄ or N at each occurrence, and X is C when X is at a fused site;
Y is independently selected from CR₅R₆, NR₇, S, or O at each occurrence;
R₁-R₇ are each independently selected from H, D, a C₁₋₂₀ linear alkyl group, a C₁₋₂₀ linear alkoxyl group, a C₁₋₂₀ linear thioalkoxyl group, a C₃₋₂₀ branched alkyl group, a C₂₋₂₀ cycloalkyl group, a C₃₋₂₀ branched alkoxyl group, a C₂₋₂₀ cycloalkoxy group, a C₃₋₂₀ branched thioalkoxyl group, a C₂₋₂₀ thiocycloalkoxy group, a methylsilyl group, a ketone group, an alkoxycarbonyl group, an aryloxycarbonyl group, a substituted or unsubstituted aromatic group containing 6-40 ring atoms, a substituted or unsubstituted heteroaromatic group containing 5-40 ring atom, a substituted or unsubstituted aryloxy group containing 6-40 ring atoms, a substituted or unsubstituted heteroaryloxy group containing 5-40 ring atoms, a cyanoyl group, a carbamoyl group, a haloformyl group, a formyl group, an isocyano group, an isocyanate group, a thiocyanate group, an isothiocyanate group, a hydroxyl group, a nitro group, an amino group, CF₃, Cl, Br, F, I, or combinations thereof at each occurrence;
n₁, n₂, and n₃ are each independently selected from 0, 1, 2, or 3, m₁ and m₂ are each independently selected from 0, 1, or 2, and at least one of m₁ and m₂ is not 0; and
Ar₃ is selected from a substituted or unsubstituted aromatic group containing 6-40 carbon atoms or a substituted or unsubstituted heteroaromatic group containing 6-40 ring atoms.

2. The organic boron-nitrogen compound of claim 1, wherein Ar₁ is selected from any one of following groups:

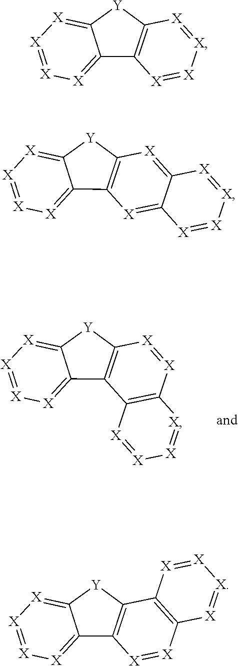

3. The organic boron-nitrogen compound of claim 2, wherein Ar₁ is selected from any one of following groups: 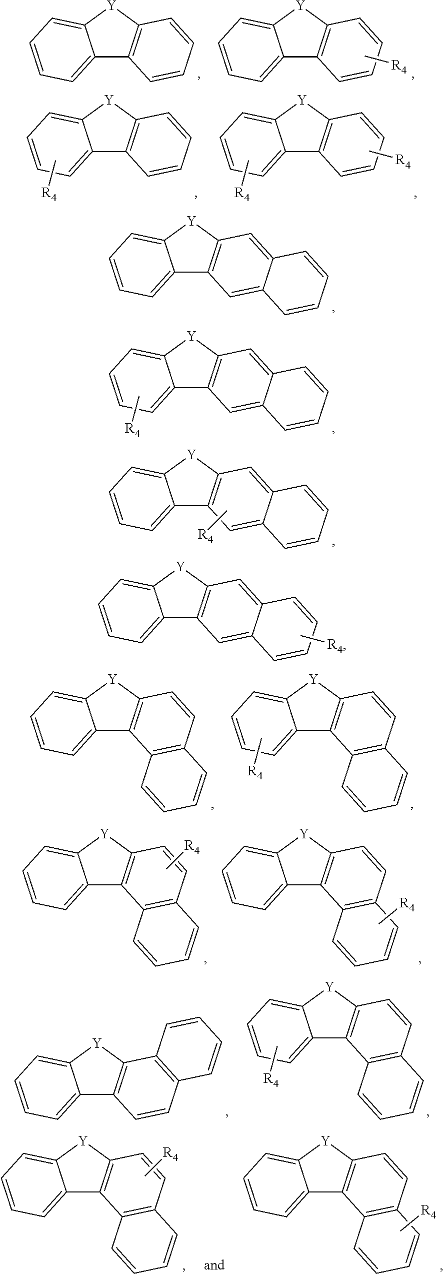
wherein R₄ and Y are defined as above.

4. The organic boron-nitrogen compound of claim 3, wherein Y is selected from any one of O, S, and following groups: 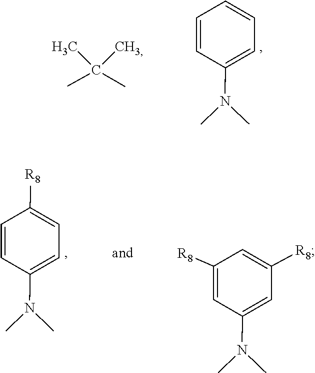
and
R₈ is independently selected from methyl, ethyl, n-propyl, iso-propyl, n-butyl, iso-butyl, tert-butyl, tert-amyl, or phenyl.

5. The organic boron-nitrogen compound of claim 1, wherein Ar₂ is selected from any one of following groups:

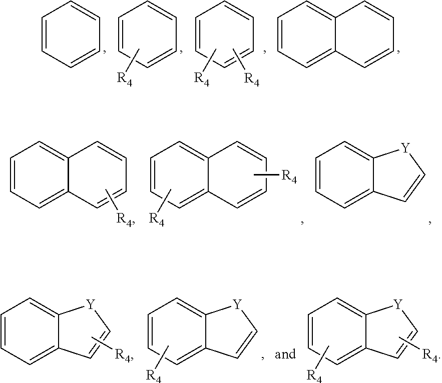

6. The organic boron-nitrogen compound of claim 1, wherein the organic boron-nitrogen compound is selected from any one of Formula (I-1) to Formula (I-9):

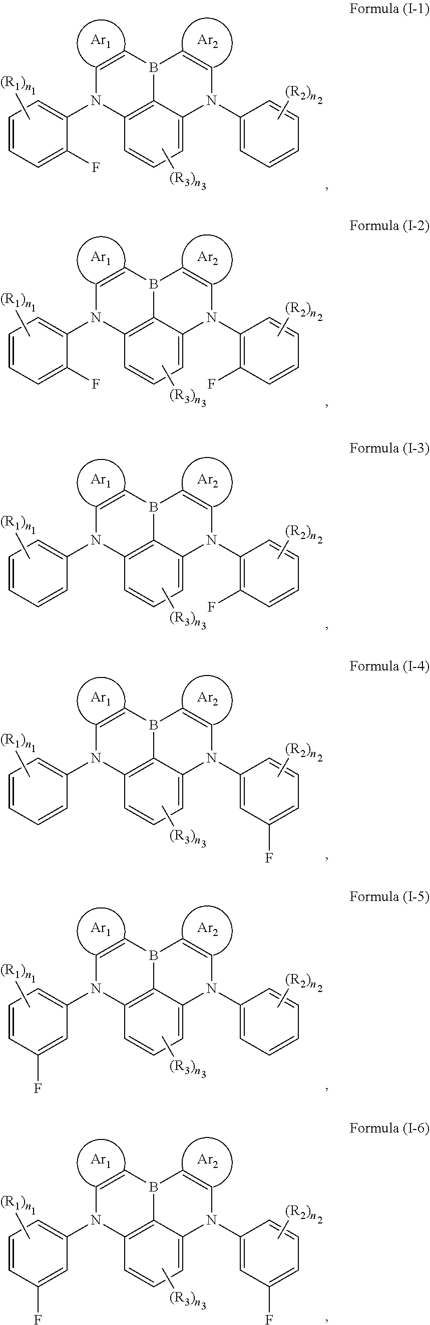

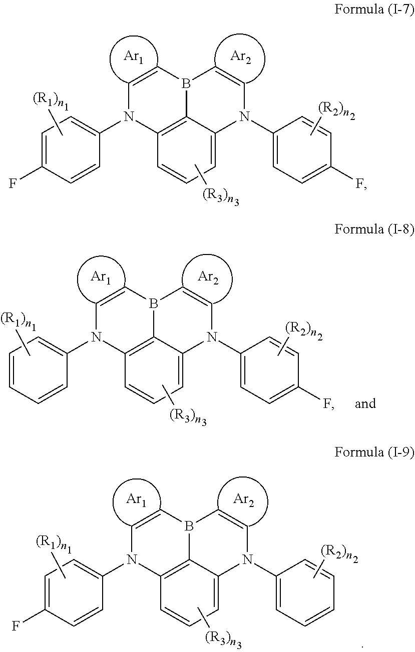

7. The organic boron-nitrogen compound of claim 6, wherein n₁, n₂, and n₃ are each independently selected from 0 or 1, and at least one of n₁, n₂, and n₃ is not 0.

8. The organic boron-nitrogen compound of claim 1, wherein R₁-R₇ are each independently selected from methyl, ethyl, n-propyl, iso-propyl, n-butyl, iso-butyl, tert-butyl, tert-amyl, or phenyl.

9. An organic electronic device comprising a cathode and an anode disposed opposite to each other, and an organic functional layer disposed between the cathode and the anode, wherein a material of the organic functional layer comprises an organic boron-nitrogen compound represented by Formula (I): 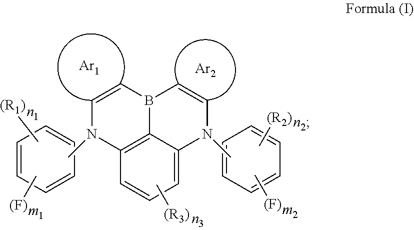
wherein Ar₁ is represented by following formula: 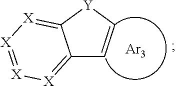
and
Ar₂ is represented by any one of following formulas: 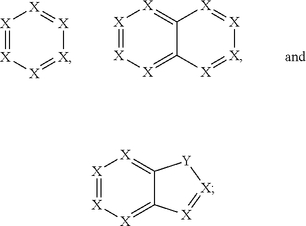
wherein X is independently selected from CR₄ or N at each occurrence, and X is C when X is at a fused site;
Y is independently selected from CR₅R₆, NR₇, S, or O at each occurrence;
R₁-R₇ are each independently selected from H, D, a C₁₋₂₀ linear alkyl group, a C₁₋₂₀ linear alkoxyl group, a C₁₋₂₀ linear thioalkoxyl group, a C₃₋₂₀ branched alkyl group, a C₂₋₂₀ cycloalkyl group, a C₃₋₂₀ branched alkoxyl group, a C₂₋₂₀ cycloalkoxy group, a C₃₋₂₀ branched thioalkoxyl group, a C₂₋₂₀ thiocycloalkoxy group, a methylsilyl group, a ketone group, an alkoxycarbonyl group, an aryloxycarbonyl group, a substituted or unsubstituted aromatic group containing 6-40 ring atoms, a substituted or unsubstituted heteroaromatic group containing 5-40 ring atom, a substituted or unsubstituted aryloxy group containing 6-40 ring atoms, a substituted or unsubstituted heteroaryloxy group containing 5-40 ring atoms, a cyanoyl group, a carbamoyl group, a haloformyl group, a formyl group, an isocyano group, an isocyanate group, a thiocyanate group, an isothiocyanate group, a hydroxyl group, a nitro group, an amino group, CF₃, Cl, Br, F, I, or combinations thereof at each occurrence;
n₁, n₂, and n₃ are each independently selected from 0, 1, 2, or 3, m₁ and m₂ are each independently selected from 0, 1, or 2, and at least one of m₁ and m₂ is not 0; and
Ar₃ is selected from a substituted or unsubstituted aromatic group containing 6-40 carbon atoms or a substituted or unsubstituted heteroaromatic group containing 6-40 ring atoms.

10. The organic electronic device of claim 9, wherein the organic functional layer comprises a light-emitting layer, a material of the light-emitting layer comprises a light-emitting host material and a light-emitting guest material, and the light-emitting guest material comprises the organic boron-nitrogen compound.

11. The organic electronic device of claim 9, wherein Ar₁ is selected from any one of following groups:

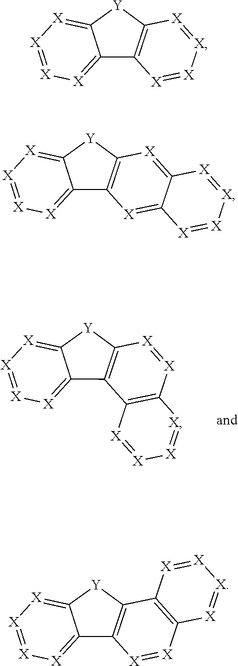

12. The organic electronic device of claim 11, wherein Ar₁ is selected from any one of following groups: 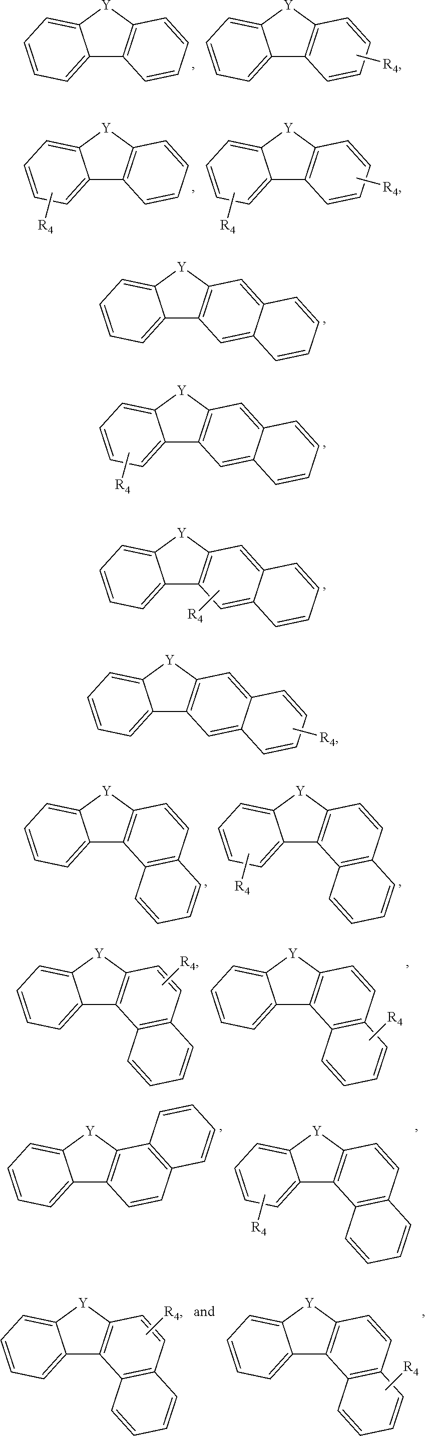
wherein R₄ and Y are defined as above.

13. The organic electronic device of claim 12, wherein Y is selected from any one of O, S, and following groups: 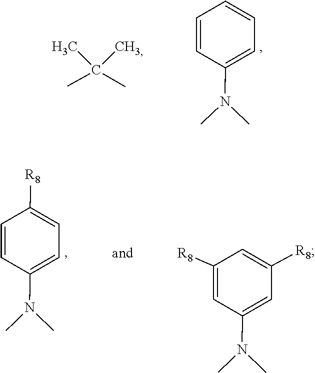
and
R₈ is independently selected from methyl, ethyl, n-propyl, iso-propyl, n-butyl, iso-butyl, tert-butyl, tert-amyl, or phenyl.

14. The organic electronic device of claim 9, wherein Ar₂ is selected from any one of following groups:

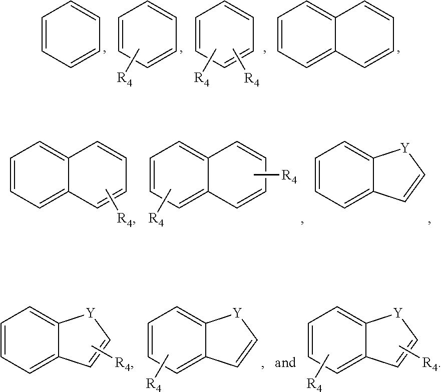

15. The organic electronic device of claim 9, wherein the organic boron-nitrogen compound is selected from any one of Formula (I-1) to Formula (I-9):

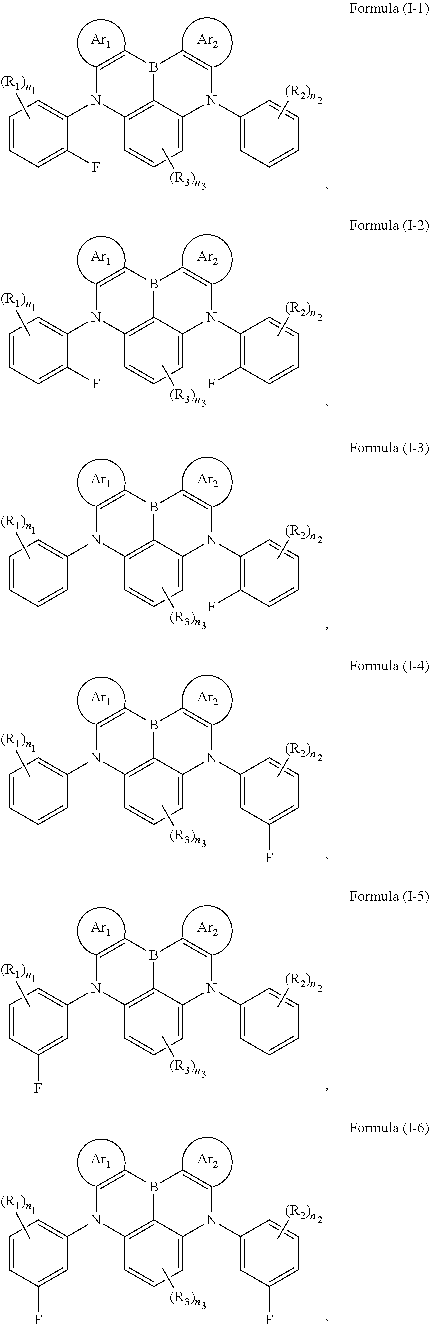

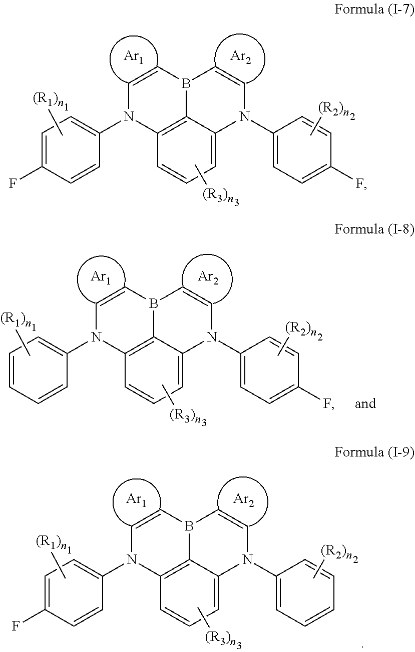

16. The organic electronic device of claim 15, wherein n₁, n₂, and n₃ are each independently selected from 0 or 1, and at least one of n₁, n₂, and n₃ is not 0.

17. The organic electronic device of claim 9, wherein R₁-R₇ are each independently selected from methyl, ethyl, n-propyl, iso-propyl, n-butyl, iso-butyl, tert-butyl, tert-amyl, or phenyl.

18. The organic electronic device of claim 9, wherein an emission wavelength of the organic electronic device ranges from 300 nm to 1000 nm.

19. The organic electronic device of claim 9, wherein the organic electronic device is a blue light-emitting device.

20. An electronic apparatus comprising an organic electronic device, wherein the organic electronic device comprises a cathode and an anode disposed opposite to each other, and an organic functional layer disposed between the cathode and the anode, wherein a material of the organic functional layer comprises an organic boron-nitrogen compound represented by Formula (I): 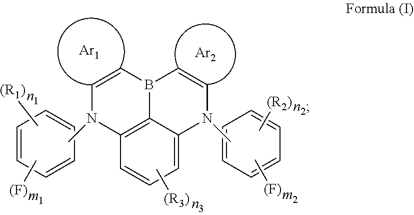
wherein Ar₁ is represented by following formula: 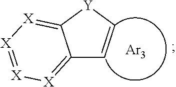
and
Ar₂ is represented by any one of following formulas: 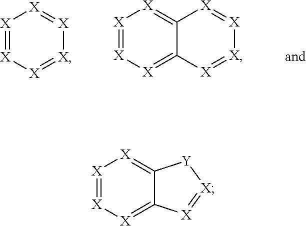
wherein X is independently selected from CR₄ or N at each occurrence, and X is C when X is at a fused site;
Y is independently selected from CR₅R₆, NR₇, S, or O at each occurrence;
R₁-R₇ are each independently selected from H, D, a C₁₋₂₀ linear alkyl group, a C₁₋₂₀ linear alkoxyl group, a C₁₋₂₀ linear thioalkoxyl group, a C₃₋₂₀ branched alkyl group, a C₂₋₂₀ cycloalkyl group, a C₃₋₂₀ branched alkoxyl group, a C₂₋₂₀ cycloalkoxy group, a C₃₋₂₀ branched thioalkoxyl group, a C₂₋₂₀ thiocycloalkoxy group, a methylsilyl group, a ketone group, an alkoxycarbonyl group, an aryloxycarbonyl group, a substituted or unsubstituted aromatic group containing 6-40 ring atoms, a substituted or unsubstituted heteroaromatic group containing 5-40 ring atom, a substituted or unsubstituted aryloxy group containing 6-40 ring atoms, a substituted or unsubstituted heteroaryloxy group containing 5-40 ring atoms, a cyanoyl group, a carbamoyl group, a haloformyl group, a formyl group, an isocyano group, an isocyanate group, a thiocyanate group, an isothiocyanate group, a hydroxyl group, a nitro group, an amino group, CF₃, Cl, Br, F, I, or combinations thereof at each occurrence;
n₁, n₂, and n₃ are each independently selected from 0, 1, 2, or 3, m₁ and m₂ are each independently selected from 0, 1, or 2, and at least one of m₁ and m₂ is not 0; and
Ar₃ is selected from a substituted or unsubstituted aromatic group containing 6-40 carbon atoms or a substituted or unsubstituted heteroaromatic group containing 6-40 ring atoms.
